(19) United States
(12) Patent Application Publication
(10) Pub. No.: US 2023/0150869 A1
(43) Pub. Date: May 18, 2023

(54) GLASS-CERAMIC ARTICLES WITH IMPROVED MECHANICAL PROPERTIES AND LOW HAZE

(71) Applicant: CORNING INCORPORATED, Corning, NY (US)

(72) Inventors: Carol Ann Click, Corning, NY (US); Qiang Fu, Painted Post, NY (US); Jill Marie Hall, Elmira, NY (US); Mathieu Gerard Jacques Hubert, Corning, NY (US); Charlene Marie Smith, Corning, NY (US); Ljerka Ukrainczyk, Ithaca, NY (US); Taylor Marie Wilkinson, Painted Post, NY (US)

(21) Appl. No.: 17/983,754

(22) Filed: Nov. 9, 2022

Related U.S. Application Data
(60) Provisional application No. 63/278,878, filed on Nov. 12, 2021.

(51) Int. Cl. C03C 21/00; C03C 10/00; H05K 5/03

(52) U.S. Cl. CPC C03C 21/002; C03C 10/0027; H05K 5/03; C03C 2204/00

(57) ABSTRACT

A glass-ceramic article having greater than or equal to 65.00 wt. % and less than or equal to 80.00 wt. % SiO₂, greater than 4.00 wt. % and less than or equal to 12.00 wt. % Al₂O₃, greater than or equal to 0.10 wt. % and less than or equal to 3.5 wt. % P₂O₅, greater than or equal to 8.00 wt. % and less than or equal to 17.00 wt. % Li₂O, greater than or equal to 4.00 wt. % and less than or equal to 15.00 wt. % ZrO₂, and greater than or equal to 0.05 wt. % and less than or equal to 4.00 wt. % CaO.

This application claims the benefit of priority under 35 U.S.C. § 119 of U.S. Provisional Application Ser. No. 63/278,878 filed on Nov. 12, 2021, the content of which is relied upon and incorporated herein by reference in its entirety.

### BACKGROUND

### Field

The present specification generally relates to glass-ceramic articles, and particularly relates to glass-ceramic articles having improved mechanical properties and low haze.

### Technical Background

There is a demand for high strength glass for portable electronic devices. Several materials are currently being utilized on the market such as glass, zirconia, plastic, metal, and glass-ceramics.

Glass-ceramics have certain advantages over other materials, but it can be difficult to form a glass-ceramic having the properties required for a high strength portable device. Accordingly, a need exists for glass-ceramic articles have improved properties and methods for making the glass-ceramic articles.

### SUMMARY

In aspect 1, a glass-ceramic article comprises: greater than or equal to 65.00 wt. % and less than or equal to 80.00 wt. % SiO₂; greater than 4.00 wt. % and less than or equal to 12.00 wt. % Al₂O₃; greater than or equal to 0.10 wt. % and less than or equal to 3.5 wt. % P₂O₅; greater than or equal to 8.00 wt. % and less than or equal to 17.00 wt. % Li₂O; greater than or equal to 4.00 wt. % and less than or equal to 15.00 wt. % ZrO₂; and greater than or equal to 0.05 wt. % and less than or equal to 4.00 wt. % CaO.

Aspect 2 includes the glass-ceramic article of aspect 1, wherein the glass-ceramic article has a haze less than 0.15 measured on a 0.6 mm thick glass-ceramic article using a BYK Hazegard I Pro Setup.

Aspect 3 includes the glass-ceramic article of any one of aspects 1 or 2, wherein the glass-ceramic article has a haze less than 0.12 measured on a 0.6 mm thick glass-ceramic article using a BYK Hazegard I Pro Setup.

Aspect 4 includes the glass-ceramic article of any one of aspects 1 to 3, wherein the glass-ceramic article has an average transmittance of 85% or greater measured at wavelengths of 450 nm to 800 nm.

Aspect 5 includes the glass-ceramic article of any one of aspects 1 to 4, wherein the glass-ceramic article comprises: greater than or equal to 30 wt % and less than or equal to 50 wt % lithium disilicate; greater than or equal to 30 wt % and less than or equal to 50 wt % petalite; and less than 5 wt % of a sum of crystalline phases other than lithium disilicate and petalite.

Aspect 6 includes the glass-ceramic article of any one of aspects 1 to 5, wherein the glass-ceramic article comprises greater than or equal to 5 wt % and less than or equal to 20 wt % residual amorphous glass.

Aspect 7 includes the glass-ceramic article of any one of aspects 1 to 6, wherein the glass-ceramic article has a weight ratio of lithium disilicate to petalite that is greater than or equal to 0.5 and less than or equal to 1.5.

Aspect 8 includes the glass article of any one of aspects 1 to 7, comprising greater than or equal to 68.00 wt. % and less than or equal to 74.00 wt. % SiO₂.

Aspect 9 includes the glass-ceramic article of any one of aspects 1 to 8, comprising greater than 5.00 wt. % and less than or equal to 9.00 wt. % Al₂O₃.

Aspect 10 includes the glass-ceramic article of any one of aspects 1 to 9, comprising greater than or equal to 1.00 wt. % and less than or equal to 3.00 wt. % P₂O₅.

Aspect 11 includes the glass-ceramic article of any one of aspects 1 to 10, comprising greater than or equal to 9.00 wt. % and less than or equal to 14.00 wt. % Li₂O.

Aspect 12 includes the glass-ceramic article of any one of aspects 1 to 11, comprising greater than or equal to 4.50 wt. % and less than or equal to 8.00 wt. % ZrO₂.

Aspect 13 includes the glass-ceramic article of any one of aspects 1 to 12, comprising greater than or equal to 0.10 wt. % and less than or equal to 1.00 wt. % CaO.

Aspect 14 includes the glass-ceramic article of any one of aspects 1 to 13, comprising greater than or equal to 0.01 wt % and less than or equal to 0.5 wt % SnO₂.

Aspect 15 includes the glass-ceramic article of any one of aspects 1 to 14, wherein the glass-ceramic article has a thickness that is greater than or equal to 0.1 mm and less than or equal to 2.0 mm.

Aspect 16 includes the glass-ceramic article of any one of aspects 1 to 15, wherein the glass-ceramic article has a thickness that is greater than or equal to 0.1 mm and less than or equal to 1.0 mm.

Aspect 17 includes an electronic device comprising: a housing, a display, a cover substrate adjacent to the display, wherein the cover substrate comprises the glass-ceramic article of any one of aspects 1 to 16.

Aspect 18 is a strengthened glass-ceramic article comprising: a first surface; a second surface; and a thickness t extending from the first surface to the second surface, wherein the strengthened glass-ceramic article has a surface compressive stress at the first surface, stress transitions from compressive stress to a tensile stress at a depth from greater than or equal to 0.15 t and less than or equal to 0.25 t measured from the first surface toward a centerline of the strengthened glass-ceramic article, and the strengthened glass-ceramic article has a maximum central tension mCT, and an absolute value of the surface compressive stress measured at the first surface is greater than or equal to 1.5 mCT and less than or equal to 2.5 mCT.

Aspect 19 includes the strengthened glass-ceramic article of aspect 18, wherein a compressive stress decreases with increasing thickness measured from the first surface of the strengthened glass-ceramic article to the centerline of the strengthened glass-ceramic article in a linear function from a thickness of greater than or equal to 0.07 t to a thickness of 0.26 t.

Aspect 20 includes the strengthened glass-ceramic article of any one of aspects 17 or 19, wherein the strengthened glass-ceramic article has a compressive stress that is greater than or equal to 250 MPa and less than or equal to 400 MPa.

Aspect 21 includes the strengthened glass-ceramic article of any one of aspects 17 to 20, wherein the strengthened glass-ceramic article has a compressive stress that is greater than or equal to 300 MPa and less than or equal to 400 MPa.

Aspect 22 includes the strengthened glass-ceramic article of any one of aspects 17 to 21, wherein the strengthened glass-ceramic article has a central tension that is greater than or equal to 100 MPa and less than or equal to 170 MPa.

Aspect 23 includes the strengthened glass-ceramic article of any one of aspects 17 to 22, wherein the strengthened glass-ceramic article has a central tension that is greater than or equal to 140 MPa and less than or equal to 170 MPa.

Aspect 24 includes the strengthened glass-ceramic article of any one of aspects 17 to 23, wherein the strengthened glass-ceramic article has a stored strain energy that is greater than or equal to 22 J/m² and less than or equal to 60 J/m².

Aspect 25 includes the strengthened glass-ceramic article of any one of aspects 17 to 22, wherein the strengthened glass-ceramic article has a fracture toughness that is greater than or equal to 1.0 MPa√m and less than or equal to 2.0 MPa√m.

Aspect 26 includes the strengthened glass-ceramic article of any one of aspects 17 to 23, wherein the strengthened glass-ceramic article has a haze less than 0.15 measured on a 0.6 mm thick glass-ceramic article using a BYK Hazegard I Pro Setup.

Aspect 26 includes the strengthened glass-ceramic article of any one of aspects 17 to 26, wherein the strengthened glass-ceramic article has a density that is greater than or equal to 2.40 g/cm³ and less than or equal to 2.60 g/cm³.

Aspect 27 includes the strengthened glass-ceramic article of any one of aspects 17 to 27, wherein the strengthened glass-ceramic article has a fracture strength measured on a glass-ceramic article having a thickness of 0.6 mm using 80 grit is greater than or equal to 350 MPa and less than or equal to 450 MPa.

Aspect 28 includes the strengthened glass-ceramic article of any one of aspects 17 to 27, wherein the strengthened glass-ceramic article has a fracture strength measured on a glass-ceramic article having a thickness of 0.6 mm using 80 grit is greater than or equal to 350 MPa and less than or equal to 450 MPa.

Aspect 29 includes the strengthened glass-ceramic article of any one of claims 17 to 27, wherein the strengthened glass-ceramic article has: a maximum compressive stress greater than or equal to 300 MPa and less than or equal to 400 MPa; a maximum central tension from greater than or equal to 120 MPa and less than or equal to 170 MPa, and a fracture stress of greater than or equal to 450 MPa and less than or equal to 550 MPa√measured on a strengthened glass-ceramic article have a thickness of 0.6 mm.

Aspect 30 includes the strengthened glass-ceramic article of any one of aspects 17 to 29, wherein the strengthened glass-ceramic article comprises at its center: greater than or equal to 65.00 wt. % and less than or equal to 80.00 wt. % SiO₂; greater than or equal to 8.00 wt. % and less than or equal to 17.00 wt. % Li₂O; and greater than or equal to 4.00 wt. % and less than or equal to 15.00 wt. % ZrO₂.

Aspect 31 includes the strengthened glass-ceramic article of any one of aspects 17 to 30, wherein the strengthened glass-ceramic article comprises at its center greater than 4.00 wt. % and less than or equal to 12.00 wt. % Al₂O₃.

Aspect 32 includes the strengthened glass-ceramic article of any one of aspects 17 to 31, wherein the strengthened glass-ceramic article comprises at its center greater than or equal to 0.10 wt. % and less than or equal to 3.5 wt. % P₂O₅.

Aspect 33 includes the strengthened glass-ceramic article of any one of aspects 17 to 32, wherein the strengthened glass-ceramic article comprises at its center greater than or equal to 0.05 wt. % and less than or equal to 4.00 wt. % CaO.

Aspect 34 includes the strengthened glass-ceramic article of any one of aspects 17 to 33, comprising at its center greater than or equal to 68.00 wt. % and less than or equal to 74.00 wt. % SiO₂.

Aspect 35 includes the strengthened glass-ceramic article of any one of aspects 17 to 34, comprising at its center greater than 5.00 wt. % and less than or equal to 9.00 wt. % Al₂O₃.

Aspect 36 includes the strengthened glass-ceramic article of any one of aspects 17 to 35, comprising at its center greater than or equal to 1.00 wt. % and less than or equal to 3.00 wt. % P₂O₅.

Aspect 37 includes the strengthened glass-ceramic article of any one of aspects 17 to 36, comprising at its center greater than or equal to 9.00 wt. % and less than or equal to 14.00 wt. % Li₂O.

Aspect 38 includes the strengthened glass-ceramic article of any one of aspects 17 to 37, comprising at its center greater than or equal to 4.50 wt. % and less than or equal to 8.00 wt. % ZrO₂.

Aspect 39 includes the strengthened glass-ceramic article of any one of aspects 17 to 38, comprising at its center greater than or equal to 0.10 wt. % and less than or equal to 1.00 wt. % CaO.

Aspect 40 includes the strengthened glass-ceramic article of any one of aspects 17 to 39, comprising at its center greater than or equal to 0.01 wt. % and less than or equal to 0.5 wt. % SnO₂.

Aspect 41 includes the strengthened glass-ceramic article of any one of aspects 17 to 40, wherein the strengthened glass-ceramic article comprises: greater than or equal to 30 wt % and less than or equal to 50 wt % lithium disilicate; greater than or equal to 30 wt % and less than or equal to 50 wt % petalite; and less than 3 wt % of a sum of crystalline phases other than lithium disilicate and petalite.

Aspect 42 includes the strengthened glass-ceramic article of any one of aspects 17 to 41, wherein the strengthened glass-ceramic article comprises greater than or equal to 5 wt % and less than or equal to 20 wt % residual amorphous glass.

Aspect 43 includes the strengthened glass-ceramic article any one of aspects 17 to 42, wherein the strengthened glass-ceramic article has a weight ratio of lithium disilicate to petalite that is greater than or equal to 0.5 and less than or equal to 1.5.

Aspect 44 includes the strengthened glass-ceramic article of any one of aspects 17 to 43, wherein the strengthened glass-ceramic article has a haze less than 0.15 measured on a 0.6 mm thick glass-ceramic article using a BYK Hazegard I Pro Setup.

Aspect 45 includes the strengthened glass-ceramic article of any one of aspects 17 to 44, wherein the strengthened glass-ceramic article has a haze less than 0.12 measured on a 0.6 mm thick glass-ceramic article using a BYK Hazegard I Pro Setup.

Aspect 46 includes the strengthened glass-ceramic article of any one of aspects 17 to 45, wherein the strengthened glass-ceramic article has an average transmittance of 85% or greater measured at wavelengths of 450 nm to 800 nm.

Aspect 47 includes the strengthened glass-ceramic article of any one of aspects 17 to 46, wherein the strengthened glass-ceramic article has a thickness that is greater than or equal to 0.1 mm and less than or equal to 2.0 mm.

Aspect 48 includes the strengthened glass-ceramic article of any one of aspects 17 to 47, wherein the strengthened glass-ceramic article has a thickness that is greater than or equal to 0.1 mm and less than or equal to 1.0 mm.

Aspect 49 includes an electronic device comprising: a housing, a display, a cover substrate adjacent to the display, wherein the cover substrate comprises the strengthened glass-ceramic article of any one of aspects 17 to 48.

Aspect 50 is a method for forming a glass-ceramic comprising: heating a precursor glass composition to a nucleation temperature, wherein the nucleation temperature is greater than or equal to 550° C. and less than or equal to 650° C.; holding the precursor glass composition for a first duration in a temperature range that is greater than or equal to the nucleation temperature and less than or equal to 650° C. to form a nucleated precursor glass composition; heating the nucleated precursor glass composition to a growth temperature, wherein the growth temperature is greater than or equal to 680° C. and less than or equal to 800° C.; and holding the nucleated precursor glass composition for a second duration in a temperature range that is greater than or equal to the growth temperature and less than or equal to 800° C. to form the glass-ceramic.

Aspect 51 includes the method of aspect 50, wherein the first duration and the second duration are each greater than or equal to 1 minute to less than or equal to 240 minutes.

Aspect 52 includes the method of any one of aspects 48 or 51, wherein holding the precursor glass composition for a first duration in a temperature range that is greater than or equal to the nucleation temperature and less than or equal to 650° C. is an isothermal hold at the nucleation temperature for the first duration.

Aspect 53 includes the method of any one of aspects 48 to 52, wherein holding the nucleated precursor glass composition for a second duration in a temperature range that is greater than or equal to the growth temperature and less than or equal to 800° C. comprises an isothermal hold at the growth temperature for the second duration.

Aspect 54 includes the method of any one of aspects 48 to 53, wherein holding the precursor glass composition for a first duration in a temperature range that is greater than or equal to the nucleation temperature and less than or equal to 650° C. comprises heating the precursor glass composition from the nucleation temperature to a temperature that is less than or equal to 650° C. for the first duration.

Aspect 55 includes the method of any one of aspects 48 to 54, wherein holding the nucleated precursor glass composition for a second duration in a temperature range that is greater than or equal to the growth temperature and less than or equal to 800° C. comprises heating the nucleated precursor glass composition from the growth temperature to a temperature that is less than or equal to 800° C. for the second duration.

Aspect 56 includes the method of any one of aspects 48 to 55, wherein heating a precursor glass composition to a nucleation temperature, wherein the nucleation temperature is greater than or equal to 550° C. and less than or equal to 650° C. and heating the nucleated precursor glass composition to a growth temperature, wherein the growth temperature is greater than or equal to 680° C. and less than or equal to 800° C. comprises heating the precursor glass composition and the nucleated precursor glass composition is conducted at a heating rate that is greater than or equal to 0.1° C./min and less than or equal to 50° C./min.

Aspect 57 includes the method of any one of aspects 48 to 56, further comprising: exposing the glass-ceramic to an ion exchange medium comprising a molten potassium salt, a molten sodium salt, and a molten lithium salt to form a strengthened glass-ceramic.

Aspect 58 includes the method of aspect 57, wherein the ion exchange medium comprises: greater than or equal to 50 wt % and less than or equal to 70 wt % KNO₃; greater than or equal to 30 wt % and less than or equal to 50 wt % NaNO₃; and greater than or equal to 0.05 wt % and less than or equal to 0.15 wt % LiNO₃.

Aspect 59 includes the method of any one of aspects 55 or 58, wherein the ion exchange medium comprises greater than or equal to 0.08 wt % and less than or equal to 0.12 wt % LiNO₃.

Aspect 60 includes the method of any one of aspects 55 to 59, wherein the ion exchange medium further comprises NaNO₂ and silicic acid.

Aspect 61 includes the method of any one of aspects 55 to 60, wherein a temperature of the ion exchange medium during exposure to the glass-ceramic is greater than or equal to 450° C. and less than or equal to 550° C., and the glass-ceramic is exposed to the ion exchange medium for a duration hat is greater than or equal to 1 hour and less than or equal to 16 hours.

Aspect 62 is a glass article comprising at its center: greater than or equal to 65.00 wt. % and less than or equal to 80.00 wt. % SiO₂; greater than 4.00 wt. % and less than or equal to 12.00 wt. % Al₂O₃; greater than or equal to 0.10 wt. % and less than or equal to 3.5 wt. % P₂O₅; greater than or equal to 8.00 wt. % and less than or equal to 17.00 wt. % Li₂O; greater than or equal to 4.00 wt. % and less than or equal to 15.00 wt. % ZrO₂; and greater than or equal to 0.05 wt. % and less than or equal to 4.00 wt. % CaO.

Aspect 63 includes the glass article of aspect 62, comprising at its center greater than or equal to 68.00 wt. % and less than or equal to 74.00 wt. % SiO₂.

Aspect 64 includes the glass article of any one of aspects 60 or 63, comprising at its center greater than 5.00 wt. % and less than or equal to 9.00 wt. % Al₂O₃.

Aspect 65 includes the glass article of any one of aspects 60 to 64, comprising at its center greater than or equal to 1.00 wt. % and less than or equal to 3.00 wt. % P₂O₅.

Aspect 66 includes the glass article of any one of aspects 60 to 65, comprising at its center greater than or equal to 9.00 wt. % and less than or equal to 14.00 wt. % Li₂O.

Aspect 67 includes the glass article of any one of aspects 60 to 66, comprising at its center greater than or equal to 4.50 wt. % and less than or equal to 8.00 wt. % ZrO₂.

Aspect 68 includes the glass article of any one of aspects 60 to 67, comprising at its center greater than or equal to 0.10 wt. % and less than or equal to 1.00 wt. % CaO.

Aspect 69 includes the glass article of any one of aspects 60 to 68, comprising at its center greater than or equal to 0.01 wt. % and less than or equal to 0.5 wt. % SnO₂.

Aspect 70 includes the glass article of any one of aspects 60 to 69, wherein the glass-ceramic article has a haze less than 0.15 measured on a 0.6 mm thick glass-ceramic article using a BYK Hazegard I Pro Setup.

Aspect 71 includes the glass article of any one of aspects 60 to 70, wherein the glass-ceramic article has a haze less than 0.12 measured on a 0.6 mm thick glass-ceramic article using a BYK Hazegard I Pro Setup.

Aspect 72 includes the glass article of any one of aspects 60 to 71, wherein the glass-ceramic article has an average transmittance of 85% or greater.

Aspect 73 includes the glass article of any one of aspects 60 to 72, wherein the glass article has a thickness that is greater than or equal to 0.1 mm and less than or equal to 2.0 mm.

Aspect 74 includes the glass article of any one of aspects 60 to 73, wherein the glass article has a thickness that is greater than or equal to 0.1 mm and less than or equal to 1.0 mm.

Aspect 75 includes an electronic device comprising a housing, a display, a cover substrate adjacent to the display, wherein the cover substrate comprises the glass article of any one of aspects 60 to 74.

### BRIEF DESCRIPTION OF THE DRAWINGS

FIG. 1 is a flow chart that depicts methods according to embodiments disclosed and described herein;

FIG. 2 schematically depicts a cross section of a glass-ceramic article that has been chemically strengthened by ion exchange treatment;

FIG. 3 depicts fluorescent speckle microscope (FSM) images of glass-ceramics chemically strengthened by ion exchange treatment with varying amounts of lithium in the ion exchange medium;

FIG. 4A-FIG. 4C depict corrosion of glass-ceramics chemically strengthened by ion exchange treatment with varying amounts of lithium in the ion exchange medium;

FIG. 5A and FIG. 5B depict corrosion of comparative glass-ceramics chemically strengthened by ion exchange treatment with varying amounts of lithium in the ion exchange medium;

FIG. 6 depicts x-ray diffraction of an assemblage of glass-ceramics made according to embodiments disclosed and described herein;

FIG. 7A graphically depicts the stress profile 0.6 mm thick glass-ceramic articles made according to embodiments disclosed and described herein;

FIG. 7B graphically depicts the stress profile 0.5 mm thick glass-ceramic articles made according to embodiments disclosed and described herein;

FIG. 7C graphically depicts central tension as a function of duration of ion exchange process;

FIG. 8 graphically depicts the results of fracture stress testing of glass-ceramics having varying thicknesses;

FIG. 9 graphically depicts the results of fracture stress testing of glass-ceramics chemically strengthened at various temperatures;

FIG. 10 graphically depicts stress profiles of glass-ceramics;

FIG. 11 graphically depicts drop testing of glass-ceramics having varying thicknesses;

FIG. 12A-FIG. 12B show the results of scratch testing;

FIG. 13A and FIG. 13B schematically depict an electronic device housing a glass or glass-ceramic article according to embodiments disclosed and described herein;

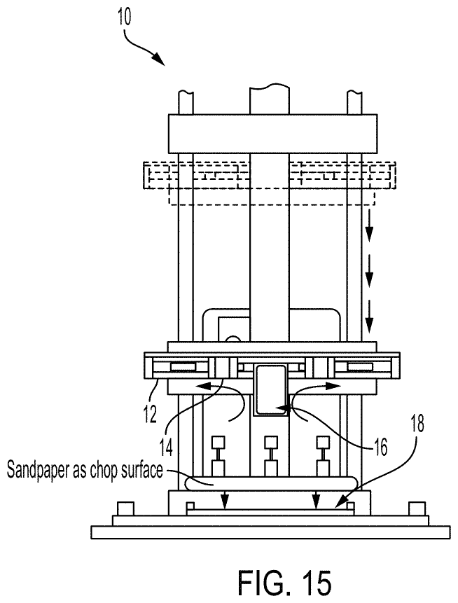

FIG. 14-FIG. 16 schematically depict a drop test apparatus.

### DETAILED DESCRIPTION

Reference will now be made in detail to embodiments of cerammed glass articles and methods for ceramming glass articles having advantageous properties; embodiments of which are illustrated in the accompanying drawings. Various embodiments will be described herein with specific reference to the appended drawings.

### Definitions and Measurement Techniques

As used herein, the term “glass-ceramic” are solids prepared by controlled crystallization of a precursor glass and have one or more crystalline phases and a residual glass phase.

As used herein, “depth of compression” or “DOC” refers to the depth of a compressive stress (CS) layer and is the depth at which the stress within a glass-ceramic article changes from compressive stress to tensile stress and has a stress value of zero. According to the convention normally used in the art, compressive stress is expressed as a negative (<0) stress and tensile stress is expressed as a positive (>0) stress. Throughout this description, however, and unless otherwise noted, CS is expressed as a positive or absolute value—that is, as recited herein, CS=|CS|.

The CS, DOC, and maximum central tension (CT) values are measured using a hybrid method that combines measurements made using evanescent prism coupling spectroscopy (EPCS) and light scattering polarimetry (LSP) as disclosed in U.S. Patent Application Publication No. 2020/0300615, which is incorporated herein by reference in its entirety.

Fracture toughness (Kic) represents the ability of a glass composition to resist fracture. Fracture toughness is measured on a non-chemically strengthened glass article, such as measuring the Kic value prior to ion exchange (IOX) treatment of the glass article, thereby representing a feature of a glass substrate prior to IOX. The fracture toughness test methods described herein are not suitable for glasses that have been exposed to IOX treatment. But, fracture toughness measurements performed as described herein on the same glass prior to IOX treatment (e.g., glass substrates) correlate to fracture toughness after IOX treatment, and are accordingly used as such. The chevron notched short bar (CNSB) method utilized to measure the Kic value is disclosed in Reddy, K. P. R. et al, “Fracture Toughness Measurement of Glass and Ceramic Materials Using Chevron-Notched Specimens,” J. Am. Ceram. Soc., 71 [6], C-310-C-313 (1988) except that Y*m is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). The double torsion method and fixture utilized to measure the Kic value is described in Shyam, A. and Lara-Curzio, E., “The double-torsion testing technique for determination of fracture toughness and slow crack growth of materials: A review,” J. Mater. Sci., 41, pp. 4093-4104, (2006). The double torsion measurement method generally produces Kic values that are slightly higher than the chevron notched short bar method. Unless otherwise specified, all fracture toughness values were measured by chevron notched short bar (CNSB) method.

The Young's modulus values recited in this disclosure refer to a value as measured by a resonant ultrasonic spectroscopy technique of the general type set forth in ASTM E2001-13.

Haze of a glass-ceramic article is measured using a haze meter, such as the BYK Gardner Haze-Gard I, such as following ASTM D1003 or ASTM D1044 on a glass article having a thickness of 0.6 mm unless otherwise stated.

Optical transmission is measured in the 250-1000 nm range on optically polished samples with plane parallel faces using a Perkin Elmer Lambda 950 spectrophotometer, with data interval of 2 nm. The transmission is measured on the glass-ceramic article itself without any coatings or other applications.

X-ray diffraction (XRD) is measured on powdered samples using a Bruker D4 Endeavor equipped with Cu radiation and a LynxEye detector. The phase assemblage is calculated using Rietveld method and using Bruker's Topas software package.

Scratch resistance was measured using an Anton Paar MicroCombi using a diamond tip with a 90 degree angle, 10 μm radius was used for testing; scratching at 5 mm/min, with a 0.14 N/sec load and unload rate. 10 mm scratches were performed.

Density is measured according to as measured in accordance with ASTM C693.

Hardness is measured using a MITUTOYO HM 114 Hardness testing machine with a Vickers indenter with a 200 gram indentation load (Dwell time is 15 seconds). Measurement of indentation diagonals is performed using calibrated optical microscopy. Values are average of measurements from 5 indentations per sample. Tests are performed on optically polished samples with plane parallel faces.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation; and the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

Directional terms as used herein—for example up, down, right, left, front, back, top, bottom, vertical, horizontal—are made only with reference to the figures as drawn and are not intended to imply absolute orientation unless otherwise expressly stated.

As used herein, the terms “warp” and “flatness”—and any variations thereof—are used interchangeably and have the same meaning.

Any ranges used herein include all ranges and subranges and any values there between unless explicitly stated otherwise.

### General Overview of Glass-Ceramic Articles

Reference will now be made in detail to the present preferred embodiment(s), examples of which is/are illustrated in the accompanying drawings. Whenever possible, the same reference numerals will be used throughout the drawings to refer to the same or like parts.

Glass-ceramic articles have attributes that can be tailored for use as cover substrates and/or housings for mobile electronic devices. For example, without being bound by theory, glass-ceramic articles with high fracture toughness and/or Young's modulus can provide resistance to crack penetration and drop performance. When such glass-ceramic articles are chemically strengthened, for example through ion exchange, the resistance to crack penetration and drop performance can be further enhanced. And the high fracture toughness and/or Young's modulus can also increase the amount of stored tensile energy and maximum central tension that can be imparted to the glass-ceramic article through chemical tempering while maintaining desirable fragmentation of the glass-ceramic article upon fracture. As another example, the optical characteristics of the glass-ceramic articles, such as transparency and haze, can be tailored through adjusting the heating/ceramming schedule used to turn a glass article into a glass-ceramic article as well as through chemical strengthening, such as through ion exchange, to design or control the properties of the glass-ceramic article.

### Composition of Glass or Glass-Ceramic Precursors

As glass and glass-ceramics are required to get thinner to meet the needs electronic devices that are getting smaller and thinner, it is desired to increase the strength of thin glass and glass-ceramic articles by increasing the levels of stress (both compressive and tensile) imparted on the glass or glass-ceramic, such as through chemical strengthening (e.g., ion exchange). However, known glass and glass ceramic compositions and methods for making such glass and glass-ceramic articles have shown a plateau of stress that can be imparted into a glass or glass-ceramic article. Accordingly, a problem addressed by glass or glass-ceramic articles disclosed and described herein is the plateau of stress (and thereby strength) that can be imparted to glass or glass-ceramic articles.

One compositional aspect that attributes to improved stress levels in glass or glass-ceramic articles according to embodiments disclosed and described herein is an increased amount of Li₂O in the glass precursor composition. Lithium is the smallest of alkali metal ions and when lithium is replaced in the glass matrix with sodium or potassium ions upon ion exchange chemical treatment, high compressive stress and central tension values may be achieved. However, including too much lithium in the glass precursor can make the glass composition difficult to melt, which can make it difficult to achieve the thin glass-ceramic articles desirable for handheld electronic devices, such as mobile phones and tablets. Accordingly, one cannot simply increase the amount of lithium in a glass precursor material to improve the compressive stress and central tension values. Doing so will result in glass compositions that cannot be easily and economically formed into thin sheets.

It has been found that including relatively high amounts of zirconia (ZrO₂) in the glass precursor composition in combination with a slightly higher amount of lithium in the glass precursor composition can yield higher compressive stress and central tension in the glass-ceramics without unduly effecting the meltability of the glass precursor. Without being bound by any particular theory, it is believe that when forming a glass-ceramic via heat treatments-which will be described in more detail below-zirconia helps to trap lithium in the residual amorphous glass phase of the glass-ceramic. Thus, more lithium is present in the residual amorphous glass phase and is readily available to be ion-exchanged with sodium and potassium during a chemical strengthening processes. Accordingly, while zirconia is traditionally included in glass and glass-ceramic compositions to prevent devitrification in the glass before it is cerammed, the relatively high amounts of zirconia included in embodiments disclosed and described herein goes beyond what is traditionally thought to improve the devitrification of the precursor glass and has been found to improve the ion exchange profile of the glass-ceramic.

Precursor glass compositions according to embodiments disclosed and described herein also include relatively high amounts of calcium oxide (CaO). Without being bound by any particular theory, it is believed that the additional calcium oxide increases the density of the glass-ceramic and, therefore, slows the diffusion of ions into the glass-ceramic during chemical strengthening. This slowing of diffusion slows the ion exchange process, but results in glass-ceramics with more compressive stress and central tension than less dense glasses. It is also believed that zirconia helps to increase the density of the glass-ceramic.

As mentioned previously, the combination of increased amounts of Li₂O, ZrO₂, and CaO, when correctly balanced, in the precursor glass composition yields a better ion exchange profile (e.g., compressive stress and central tension) than conventional precursor glass compositions that do not balance an increase of these components.

In various embodiments, the glass composition is selected such that the resultant glass-ceramic article has a crystalline phase that primarily comprises a petalite crystalline phase and a lithium silicate crystalline phase and wherein the petalite crystalline phase and the lithium silicate crystalline phase have higher weight percentages than other crystalline phases present in the glass-ceramic article.

By way of example and not limitation, in various embodiments, the glass sheets may be formed from a glass composition including greater than or equal to 65 wt % and less than or equal to 80 wt % SiO₂, greater than or equal to 4 wt % and less than or equal to 12 wt % Al₂O₃, greater than or equal to 0.10 wt % and less than or equal to 3.5 wt % P₂O₅, greater than or equal to 8 wt % and less than or equal to 17 wt % Li₂O, greater than or equal to 4 and less than or equal to 15 wt % ZrO₂, and greater than or equal to 0.05 wt % and less than or equal to 4 wt % CaO. In embodiments, the glass composition may further include greater than 0 wt % and less than or equal to 2 wt % Na₂O, greater than 0 wt % and less than or equal to 2 wt % K₂O, greater than 0 wt % and less than or equal to 1.5 wt % Fe₂O₃, and combinations thereof.

SiO₂, an oxide involved in the formation of glass, can function to stabilize the networking structure of glasses and glass-ceramics. In various glass compositions, the concentration of SiO₂ should be sufficiently high in order to form petalite crystal phase when the glass sheet is heat treated to convert to a glass-ceramic. The amount of SiO₂ may be limited to control the melting temperature of the glass, as the melting temperature of pure SiO₂ or high-SiO₂ glasses is undesirably high. In embodiments, the glass or glass-ceramic composition comprises greater than or equal to 65 wt % and less than or equal to 80 wt % SiO₂, greater than or equal to 70 wt % and less than or equal to 80 wt % SiO₂, greater than or equal to 75 wt % and less than or equal to 80 wt % SiO₂, greater than or equal to 65 wt % and less than or equal to 75 wt % SiO₂, greater than or equal to 70 wt % and less than or equal to 75 wt % SiO₂, or greater than or equal to 65 wt % and less than or equal to 70 wt % SiO₂. It should be understood that the above ranges include all subranges within the explicitly disclosed ranges.

Al₂O₃ may also provide stabilization to the network and also provides improved mechanical properties and chemical durability. If the amount of Al₂O₃ is too high, however, the fraction of lithium silicate crystals may be decreased, possibly to the extent that an interlocking structure cannot be formed. The amount of Al₂O₃ can be tailored to control viscosity. Further, if the amount of Al₂O₃ is too high, the viscosity of the melt is also generally increased. In embodiments, the glass or glass-ceramic composition comprises greater than or equal to 4 wt % and less than or equal to 12 wt % Al₂O₃, greater than or equal to 6 wt % and less than or equal to 12 wt % Al₂O₃, greater than or equal to 8 wt % and less than or equal to 12 wt % Al₂O₃, greater than or equal to 10 wt % and less than or equal to 12 wt % Al₂O₃, greater than or equal to 4 wt % and less than or equal to 10 wt % Al₂O₃, greater than or equal to 6 wt % and less than or equal to 10 wt % Al₂O₃, greater than or equal to 8 wt % and less than or equal to 10 wt % Al₂O₃, greater than or equal to 4 wt % and less than or equal to 8 wt % Al₂O₃, greater than or equal to 6 wt % and less than or equal to 8 wt % Al₂O₃, or greater than or equal to 4 wt % and less than or equal to 6 wt % Al₂O₃. It should be understood that the above ranges include all subranges within the explicitly disclosed ranges.

In the glass and glass-ceramics herein, Li₂O aids in forming both petalite and lithium silicate crystal phases. In fact, to obtain petalite and lithium silicate as the predominant crystal phases, it is desirable to have at least about 8 wt % Li₂O in the composition. Additionally, it has been found that once Li₂O approaches about 17 wt %), the composition becomes very fluid. Accordingly, in embodiments, the glass or glass-ceramic composition can comprise greater than or equal to 8 wt % and less than or equal to 17 wt % Li₂O, greater than or equal to 10 wt % and less than or equal to 17 wt % Li₂O, greater than or equal to 12 wt % and less than or equal to 17 wt % Li₂O, greater than or equal to 14 wt % and less than or equal to 17 wt % Li₂O, greater than or equal to 16 wt % and less than or equal to 17 wt % Li₂O, greater than or equal to 8 wt % and less than or equal to 16 wt % Li₂O, greater than or equal to 10 wt % and less than or equal to 16 wt % Li₂O, greater than or equal to 12 wt % and less than or equal to 16 wt % Li₂O, greater than or equal to 14 wt % and less than or equal to 16 wt % Li₂O, greater than or equal to 8 wt % and less than or equal to 14 wt % Li₂O, greater than or equal to 10 wt % and less than or equal to 14 wt % Li₂O, greater than or equal to 12 wt % and less than or equal to 14 wt % Li₂O, greater than or equal to 8 wt % and less than or equal to 12 wt % Li₂O, greater than or equal to 10 wt % and less than or equal to 12 wt % Li₂O, or greater than or equal to 8 wt % and less than or equal to 10 wt % Li₂O. It should be understood that the above ranges include all subranges within the explicitly disclosed ranges.

As noted above, Li₂O is generally useful for forming various glass-ceramics, but other alkali metal oxides tend to decrease glass-ceramic formation and form an aluminosilicate residual glass in the glass-ceramic. It has been found that more than about 5 wt % Na₂O or K₂O, or combinations thereof, leads to an undesirable amount of residual glass, which can lead to deformation during crystallization and undesirable microstructures from a mechanical property perspective. The composition of the residual glass may be tailored to control viscosity during crystallization, minimizing deformation or undesirable thermal expansion, or control microstructure properties. Therefore, in general, the glass sheets may be made from glass compositions having low amounts of non-lithium alkali metal oxides. In embodiments, the glass or glass-ceramic composition can comprise from about 0 wt % to about 5 wt % R₂O, wherein R is one or more of the alkali cations Na and K. In embodiments, the glass or glass-ceramic composition can comprise from about 1 wt % to about 3 wt % R₂O, wherein R is one or more of the alkali cations Na and K. It should be understood that, in embodiments, the glass and glass-ceramic composition does not comprise R₂O.

In embodiments, the glass and glass-ceramic composition comprise greater than 0 wt % and less than or equal to 2 wt % Na₂O, greater than or equal to 1 wt % and less than or equal to 2 wt % Na₂O, greater than 0 wt % and less than or equal to 1 wt % Na₂O. In embodiments, the glass and glass-ceramic composition comprise greater than 0 wt % and less than or equal to 2 wt % K₂O, greater than or equal to 1 wt % and less than or equal to 2 wt % K₂O, greater than 0 wt % and less than or equal to 1 wt % K₂O. It should be understood that the above ranges include all subranges within the explicitly disclosed ranges.

The glass and glass-ceramic include P₂O₅. P₂O₅ can function as a nucleating agent to produce bulk nucleation. If the concentration of P₂O₅ is too low, the precursor glass does crystallize, but only at higher temperatures (due to a lower viscosity) and from the surface inward, yielding a weak and often deformed body. However, if the concentration of P₂O₅ is too high, the devitrification, upon cooling during the formation of the glass sheets, can be difficult to control. Embodiments of glass and glass-ceramic compositions comprise greater than or equal to 0.1 wt % and less than or equal to 3.5 wt % P₂O₅, greater than or equal to 0.5 wt % and less than or equal to 3.5 wt % P₂O₅, greater than or equal to 1.0 wt % and less than or equal to 3.5 wt % P₂O₅, greater than or equal to 1.5 wt % and less than or equal to 3.5 wt % P₂O₅, greater than or equal to 2.0 wt % and less than or equal to 3.5 wt % P₂O₅, greater than or equal to 2.5 wt % and less than or equal to 3.5 wt % P₂O₅, greater than or equal to 3.0 wt % and less than or equal to 3.5 wt % P₂O₅, greater than or equal to 0.1 wt % and less than or equal to 3.0 wt % P₂O₅, greater than or equal to 0.5 wt % and less than or equal to 3.0 wt % P₂O₅, greater than or equal to 1.0 wt % and less than or equal to 3.0 wt % P₂O₅, greater than or equal to 1.5 wt % and less than or equal to 3.0 wt % P₂O₅, greater than or equal to 2.0 wt % and less than or equal to 3.0 wt % P₂O₅, greater than or equal to 2.5 wt % and less than or equal to 3.0 wt % P₂O₅, greater than or equal to 0.1 wt % and less than or equal to 2.5 wt % P₂O₅, greater than or equal to 0.5 wt % and less than or equal to 2.5 wt % P₂O₅, greater than or equal to 1.0 wt % and less than or equal to 2.5 wt % P₂O₅, greater than or equal to 1.5 wt % and less than or equal to 2.5 wt % P₂O₅, greater than or equal to 2.0 wt % and less than or equal to 2.5 wt % P₂O₅, greater than or equal to 0.1 wt % and less than or equal to 2.0 wt % P₂O₅, greater than or equal to 0.5 wt % and less than or equal to 2.0 wt % P₂O₅, greater than or equal to 1.0 wt % and less than or equal to 2.0 wt % P₂O₅, greater than or equal to 1.5 wt % and less than or equal to 2.0 wt % P₂O₅, greater than or equal to 0.1 wt % and less than or equal to 1.5 wt % P₂O₅, greater than or equal to 0.5 wt % and less than or equal to 1.5 wt % P₂O₅, greater than or equal to 1.0 wt % and less than or equal to 1.5 wt % P₂O₅, greater than or equal to 0.1 wt % and less than or equal to 1.0 wt % P₂O₅, greater than or equal to 0.5 wt % and less than or equal to 1.0 wt % P₂O₅, or greater than or equal to 0.1 wt % and less than or equal to 0.5 wt % P₂O₅. It should be understood that the above ranges include all subranges within the explicitly disclosed ranges.

In various glass and glass-ceramic compositions, it is generally found that ZrO₂ can improve the stability of Li₂O—Al₂O₃—SiO₂—P₂O₅ glass by significantly reducing glass devitrification during forming and lowering liquidus temperature. At concentrations above 8 wt %, ZrSiO₄ can form a primary liquidus phase at a high temperature, which significantly lowers liquidus viscosity. Transparent glasses can be formed when the glass contains over 2 wt % ZrO₂. The addition of ZrO₂ can also help decrease the petalite grain size, which aids in the formation of a transparent glass-ceramic. In embodiments, the glass or glass-ceramic composition comprises greater than or equal to 4 wt % and less than or equal to 15 wt % ZrO₂, greater than or equal to 6 wt % and less than or equal to 15 wt % ZrO₂, greater than or equal to 8 wt % and less than or equal to 15 wt % ZrO₂, greater than or equal to 10 wt % and less than or equal to 15 wt % ZrO₂, greater than or equal to 12 wt % and less than or equal to 15 wt % ZrO₂, greater than or equal to 14 wt % and less than or equal to 15 wt % ZrO₂, greater than or equal to 4 wt % and less than or equal to 14 wt % ZrO₂, greater than or equal to 6 wt % and less than or equal to 14 wt % ZrO₂, greater than or equal to 8 wt % and less than or equal to 14 wt % ZrO₂, greater than or equal to 10 wt % and less than or equal to 14 wt % ZrO₂, greater than or equal to 12 wt % and less than or equal to 14 wt % ZrO₂, greater than or equal to 4 wt % and less than or equal to 12 wt % ZrO₂, greater than or equal to 6 wt % and less than or equal to 12 wt % ZrO₂, greater than or equal to 8 wt % and less than or equal to 12 wt % ZrO₂, greater than or equal to 10 wt % and less than or equal to 12 wt % ZrO₂, greater than or equal to 4 wt % and less than or equal to 10 wt % ZrO₂, greater than or equal to 6 wt % and less than or equal to 10 wt % ZrO₂, greater than or equal to 8 wt % and less than or equal to 10 wt % ZrO₂, greater than or equal to 4 wt % and less than or equal to 8 wt % ZrO₂, greater than or equal to 6 wt % and less than or equal to 8 wt % ZrO₂, or greater than or equal to 4 wt % and less than or equal to 6 wt % ZrO₂. It should be understood that the above ranges include all subranges within the explicitly disclosed ranges.

CaO can enter petalite crystals in a partial solid solution. In embodiments, the glass or glass-ceramic composition comprises greater than or equal to 0.05 wt % and less than or equal to 4.0 wt %, greater than or equal to 0.1 wt % and less than or equal to 4.0 wt %, greater than or equal to 0.5 wt % and less than or equal to 4.0 wt %, greater than or equal to 1.0 wt % and less than or equal to 4.0 wt %, greater than or equal to 1.5 wt % and less than or equal to 4.0 wt %, greater than or equal to 2.0 wt % and less than or equal to 4.0 wt %, greater than or equal to 2.5 wt % and less than or equal to 4.0 wt %, greater than or equal to 3.0 wt % and less than or equal to 4.0 wt %, greater than or equal to 3.5 wt % and less than or equal to 4.0 wt %, greater than or equal to 0.05 wt % and less than or equal to 3.5 wt %, greater than or equal to 0.1 wt % and less than or equal to 3.5 wt %, greater than or equal to 0.5 wt % and less than or equal to 3.5 wt %, greater than or equal to 1.0 wt % and less than or equal to 3.5 wt %, greater than or equal to 1.5 wt % and less than or equal to 3.5 wt %, greater than or equal to 2.0 wt % and less than or equal to 3.5 wt %, greater than or equal to 2.5 wt % and less than or equal to 3.5 wt %, greater than or equal to 3.0 wt % and less than or equal to 3.5 wt %, greater than or equal to 0.05 wt % and less than or equal to 3.0 wt %, greater than or equal to 0.1 wt % and less than or equal to 3.0 wt %, greater than or equal to 0.5 wt % and less than or equal to 3.0 wt %, greater than or equal to 1.0 wt % and less than or equal to 3.0 wt %, greater than or equal to 1.5 wt % and less than or equal to 3.0 wt %, greater than or equal to 2.0 wt % and less than or equal to 3.0 wt %, greater than or equal to 2.5 wt % and less than or equal to 3.0 wt %, greater than or equal to 0.05 wt % and less than or equal to 2.5 wt %, greater than or equal to 0.1 wt % and less than or equal to 2.5 wt %, greater than or equal to 0.5 wt % and less than or equal to 2.5 wt %, greater than or equal to 1.0 wt % and less than or equal to 2.5 wt %, greater than or equal to 1.5 wt % and less than or equal to 2.5 wt %, greater than or equal to 2.0 wt % and less than or equal to 2.5 wt %, greater than or equal to 0.05 wt % and less than or equal to 2.0 wt %, greater than or equal to 0.1 wt % and less than or equal to 2.0 wt %, greater than or equal to 0.5 wt % and less than or equal to 2.0 wt %, greater than or equal to 1.0 wt % and less than or equal to 2.0 wt %, greater than or equal to 1.5 wt % and less than or equal to 2.0 wt %, greater than or equal to 0.05 wt % and less than or equal to 1.5 wt %, greater than or equal to 0.1 wt % and less than or equal to 1.5 wt %, greater than or equal to 0.5 wt % and less than or equal to 1.5 wt %, greater than or equal to 1.0 wt % and less than or equal to 1.5 wt %, greater than or equal to 0.05 wt % and less than or equal to 1.0 wt %, greater than or equal to 0.1 wt % and less than or equal to 1.0 wt %, greater than or equal to 0.5 wt % and less than or equal to 1.0 wt %, greater than or equal to 0.05 wt % and less than or equal to 0.5 wt %, greater than or equal to 0.1 wt % and less than or equal to 0.5 wt %, or greater than or equal to 0.05 wt % and less than or equal to 0.1 wt %. It should be understood that the above ranges include all subranges within the explicitly disclosed ranges.

Fe₂O₃ can lower the melting point of the glass and glass-ceramic composition. However, adding too much Fe₂O₃ can alter the color of the glass and glass-ceramic composition. In embodiments, the glass and glass-ceramic composition does not comprise Fe₂O₃. In embodiments, the glass and glass-ceramic comprises greater than 0.0 wt % and less than or equal to 1.5 wt % Fe₂O₃, greater than or equal to 0.5 wt % and less than or equal to 1.5 wt % Fe₂O₃, greater than or equal to 1.0 wt % and less than or equal to 1.5 wt % Fe₂O₃, greater than 0.0 wt % and less than or equal to 1.0 wt % Fe₂O₃, greater than or equal to 0.5 wt % and less than or equal to 1.0 wt % Fe₂O₃, or greater than 0.0 wt % and less than or equal to 0.5 wt % Fe₂O₃. It should be understood that the above ranges include all subranges within the explicitly disclosed ranges.

In various embodiments, the glass or glass-ceramic composition may further include one or more constituents, such as, by way of example and not limitation, TiO₂, CeO₂, and SnO₂. Additionally or alternatively, antimicrobial components may be added to the glass or glass-ceramic composition. Antimicrobial components that may be added to the glass or glass-ceramic may include, but are not limited to, Ag, AgO, Cu, CuO, Cu₂O, and the like. In embodiments, the glass or glass-ceramic composition may further include a chemical fining agent. Such fining agents include, but are not limited to, SnO₂, As₂O₃, Sb₂O₃, F, Cl, and Br. In embodiments, the glass or glass-ceramic includes greater than or equal to 0.01 wt % and less than or equal to 0.5 wt % SnO₂. Additional details on glass and/or glass-ceramic compositions suitable for use in various embodiments may be found in, for example, U.S. Patent Application Publication No. 2016/0102010 entitled “High Strength Glass-Ceramics Having Petalite and Lithium Silicate Structures,” filed Oct. 8, 2015, which is incorporated by reference herein in its entirety.

### Heating Conditions for Forming Glass-Ceramic Articles

The processes for making glass-ceramic according to embodiments includes heat treating the precursor glasses at two preselected temperatures for one or more preselected times to induce glass homogenization and crystallization (i.e., nucleation and growth) of one or more crystalline phases (e.g., having one or more compositions, amounts, morphologies, sizes or size distributions, etc.). These two temperatures may be referred to as the nucleation temperature and the growth temperature, respectively.

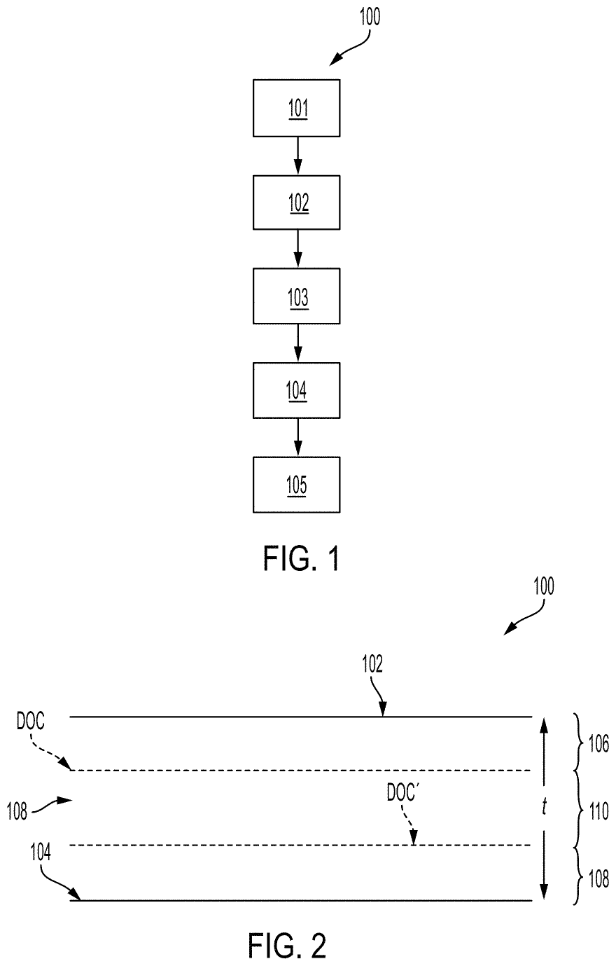

With reference now to FIG. 1, embodiments of methods for making glass ceramics 100 will generally be described. Initially, a precursor glass composition at 101 is heated to a nucleation temperature that is greater than or equal to 550° C. and less than or equal to 650° C. The precursor glass at 102 is held for a first duration in a temperature range that is greater than or equal to the nucleation temperature and less than or equal to 650° C. to form a nucleated precursor glass composition. The nucleated precursor glass composition at 103 is heated to a growth temperature that is greater than or equal to 680° C. and less than or equal to 800° C. The nucleated precursor glass composition at 104 is held for a second duration in a temperature range that is greater than or equal to the growth temperature and less than or equal to 800° C. to form the glass-ceramic. In embodiments, the glass-ceramic at 105 is exposed to an ion exchange medium comprising a molten potassium salt, a molten sodium salt, and a molten lithium salt to form a strengthened glass-ceramic. Each of these steps will be described in more detail below.

In embodiments, the nucleation stage takes place when a precursor glass is held at the predetermined nucleation temperature for a predetermined duration. In embodiments, the nucleation temperature is greater than or equal to 550° C. and less than or equal to 650° C., greater than or equal to 560° C. and less than or equal to 650° C., greater than or equal to 570° C. and less than or equal to 650° C., greater than or equal to 580° C. and less than or equal to 650° C., greater than or equal to 590° C. and less than or equal to 650° C., greater than or equal to 600° C. and less than or equal to 650° C., greater than or equal to 610° C. and less than or equal to 650° C., greater than or equal to 620° C. and less than or equal to 650° C., greater than or equal to 630° C. and less than or equal to 650° C., greater than or equal to 640° C. and less than or equal to 650° C., greater than or equal to 550° C. and less than or equal to 640° C., greater than or equal to 560° C. and less than or equal to 640° C., greater than or equal to 570° C. and less than or equal to 640° C., greater than or equal to 580° C. and less than or equal to 640° C., greater than or equal to 590° C. and less than or equal to 640° C., greater than or equal to 600° C. and less than or equal to 640° C., greater than or equal to 610° C. and less than or equal to 640° C., greater than or equal to 620° C. and less than or equal to 640° C., greater than or equal to 630° C. and less than or equal to 640° C., greater than or equal to 550° C. and less than or equal to 630° C., greater than or equal to 560° C. and less than or equal to 630° C., greater than or equal to 570° C. and less than or equal to 630° C., greater than or equal to 580° C. and less than or equal to 630° C., greater than or equal to 590° C. and less than or equal to 630° C., greater than or equal to 600° C. and less than or equal to 630° C., greater than or equal to 610° C. and less than or equal to 630° C., greater than or equal to 620° C. and less than or equal to 630° C., greater than or equal to 550° C. and less than or equal to 620° C., greater than or equal to 560° C. and less than or equal to 620° C., greater than or equal to 570° C. and less than or equal to 620° C., greater than or equal to 580° C. and less than or equal to 620° C., greater than or equal to 590° C. and less than or equal to 620° C., greater than or equal to 600° C. and less than or equal to 620° C., greater than or equal to 610° C. and less than or equal to 620° C., greater than or equal to 550° C. and less than or equal to 610° C., greater than or equal to 560° C. and less than or equal to 610° C., greater than or equal to 570° C. and less than or equal to 610° C., greater than or equal to 580° C. and less than or equal to 610° C., greater than or equal to 590° C. and less than or equal to 610° C., greater than or equal to 600° C. and less than or equal to 610° C., greater than or equal to 550° C. and less than or equal to 600° C., greater than or equal to 560° C. and less than or equal to 600° C., greater than or equal to 570° C. and less than or equal to 600° C., greater than or equal to 580° C. and less than or equal to 600° C., greater than or equal to 590° C. and less than or equal to 600° C., greater than or equal to 550° C. and less than or equal to 590° C., greater than or equal to 560° C. and less than or equal to 590° C., greater than or equal to 570° C. and less than or equal to 590° C., greater than or equal to 580° C. and less than or equal to 590° C., greater than or equal to 550° C. and less than or equal to 580° C., greater than or equal to 560° C. and less than or equal to 580° C., greater than or equal to 570° C. and less than or equal to 580° C., greater than or equal to 550° C. and less than or equal to 570° C., greater than or equal to 560° C. and less than or equal to 570° C., or greater than or equal to 550° C. and less than or equal to 560° C. It should be understood that the above ranges include all subranges within the explicitly disclosed ranges.

In embodiments, the glass is held at the nucleation temperature for a duration that is greater than or equal to 1 minute to less than or equal to 240 minutes, greater than or equal to 30 minutes to less than or equal to 240 minutes, greater than or equal to 60 minutes to less than or equal to 240 minutes, greater than or equal to 90 minutes to less than or equal to 240 minutes, greater than or equal to 120 minutes to less than or equal to 240 minutes, greater than or equal to 150 minutes to less than or equal to 240 minutes, greater than or equal to 180 minutes to less than or equal to 240 minutes, greater than or equal to 210 minutes to less than or equal to 240 minutes, greater than or equal to 1 minute to less than or equal to 210 minutes, greater than or equal to 30 minutes to less than or equal to 210 minutes, greater than or equal to 60 minutes to less than or equal to 210 minutes, greater than or equal to 90 minutes to less than or equal to 210 minutes, greater than or equal to 120 minutes to less than or equal to 210 minutes, greater than or equal to 150 minutes to less than or equal to 210 minutes, greater than or equal to 180 minutes to less than or equal to 210 minutes, greater than or equal to 1 minute to less than or equal to 180 minutes, greater than or equal to 30 minutes to less than or equal to 180 minutes, greater than or equal to 60 minutes to less than or equal to 180 minutes, greater than or equal to 90 minutes to less than or equal to 180 minutes, greater than or equal to 120 minutes to less than or equal to 180 minutes, greater than or equal to 150 minutes to less than or equal to 180 minutes, greater than or equal to 1 minute to less than or equal to 150 minutes, greater than or equal to 30 minutes to less than or equal to 150 minutes, greater than or equal to 60 minutes to less than or equal to 150 minutes, greater than or equal to 90 minutes to less than or equal to 150 minutes, greater than or equal to 120 minutes to less than or equal to 150 minutes, greater than or equal to 1 minute to less than or equal to 120 minutes, greater than or equal to 30 minutes to less than or equal to 120 minutes, greater than or equal to 60 minutes to less than or equal to 120 minutes, greater than or equal to 90 minutes to less than or equal to 120 minutes, greater than or equal to 1 minute to less than or equal to 90 minutes, greater than or equal to 30 minutes to less than or equal to 90 minutes, greater than or equal to 60 minutes to less than or equal to 90 minutes, greater than or equal to 1 minute to less than or equal to 60 minutes, greater than or equal to 30 minutes to less than or equal to 60 minutes, or greater than or equal to 1 minute to less than or equal to 30 minutes. It should be understood that the above ranges include all subranges within the explicitly disclosed ranges. After the nucleation stage, the precursor glass is referred to as a nucleated precursor glass.

The growth stage takes place when a nucleated precursor glass is held at the predetermined growth temperature for a predetermined duration. The growth temperature is, in embodiments, greater than the nucleation temperature. In embodiments, the growth temperature is greater than or equal to 680° C. and less than or equal to 800° C., greater than or equal to 690° C. and less than or equal to 800° C., greater than or equal to 700° C. and less than or equal to 800° C., greater than or equal to 710° C. and less than or equal to 800° C., greater than or equal to 720° C. and less than or equal to 800° C., greater than or equal to 730° C. and less than or equal to 800° C., greater than or equal to 740° C. and less than or equal to 800° C., greater than or equal to 750° C. and less than or equal to 800° C., greater than or equal to 760° C. and less than or equal to 800° C., greater than or equal to 770° C. and less than or equal to 800° C., greater than or equal to 780° C. and less than or equal to 800° C., greater than or equal to 790° C. and less than or equal to 800° C., greater than or equal to 680° C. and less than or equal to 790° C., greater than or equal to 690° C. and less than or equal to 790° C., greater than or equal to 700° C. and less than or equal to 790° C., greater than or equal to 710° C. and less than or equal to 790° C., greater than or equal to 720° C. and less than or equal to 790° C., greater than or equal to 730° C. and less than or equal to 790° C., greater than or equal to 740° C. and less than or equal to 790° C., greater than or equal to 750° C. and less than or equal to 790° C., greater than or equal to 760° C. and less than or equal to 790° C., greater than or equal to 770° C. and less than or equal to 790° C., greater than or equal to 780° C. and less than or equal to 790° C., greater than or equal to 680° C. and less than or equal to 780° C., greater than or equal to 690° C. and less than or equal to 780° C., greater than or equal to 700° C. and less than or equal to 780° C., greater than or equal to 710° C. and less than or equal to 780° C., greater than or equal to 720° C. and less than or equal to 780° C., greater than or equal to 730° C. and less than or equal to 780° C., greater than or equal to 740° C. and less than or equal to 780° C., greater than or equal to 750° C. and less than or equal to 780° C., greater than or equal to 760° C. and less than or equal to 780° C., greater than or equal to 770° C. and less than or equal to 780° C., greater than or equal to 680° C. and less than or equal to 770° C., greater than or equal to 690° C. and less than or equal to 770° C., greater than or equal to 700° C. and less than or equal to 770° C., greater than or equal to 710° C. and less than or equal to 770° C., greater than or equal to 720° C. and less than or equal to 770° C., greater than or equal to 730° C. and less than or equal to 770° C., greater than or equal to 740° C. and less than or equal to 770° C., greater than or equal to 750° C. and less than or equal to 770° C., greater than or equal to 760° C. and less than or equal to 770° C., greater than or equal to 680° C. and less than or equal to 760° C., greater than or equal to 690° C. and less than or equal to 760° C., greater than or equal to 700° C. and less than or equal to 760° C., greater than or equal to 710° C. and less than or equal to 760° C., greater than or equal to 720° C. and less than or equal to 760° C., greater than or equal to 730° C. and less than or equal to 760° C., greater than or equal to 740° C. and less than or equal to 760° C., greater than or equal to 750° C. and less than or equal to 760° C., greater than or equal to 680° C. and less than or equal to 750° C., greater than or equal to 690° C. and less than or equal to 750° C., greater than or equal to 700° C. and less than or equal to 750° C., greater than or equal to 710° C. and less than or equal to 750° C., greater than or equal to 720° C. and less than or equal to 750° C., greater than or equal to 730° C. and less than or equal to 750° C., greater than or equal to 740° C. and less than or equal to 750° C., greater than or equal to 680° C. and less than or equal to 740° C., greater than or equal to 690° C. and less than or equal to 740° C., greater than or equal to 700° C. and less than or equal to 740° C., greater than or equal to 710° C. and less than or equal to 740° C., greater than or equal to 720° C. and less than or equal to 740° C., greater than or equal to 730° C. and less than or equal to 740° C., greater than or equal to 680° C. and less than or equal to 730° C., greater than or equal to 690° C. and less than or equal to 730° C., greater than or equal to 700° C. and less than or equal to 730° C., greater than or equal to 710° C. and less than or equal to 730° C., greater than or equal to 720° C. and less than or equal to 730° C., greater than or equal to 680° C. and less than or equal to 720° C., greater than or equal to 690° C. and less than or equal to 720° C., greater than or equal to 700° C. and less than or equal to 720° C., greater than or equal to 710° C. and less than or equal to 720° C., greater than or equal to 680° C. and less than or equal to 710° C., greater than or equal to 690° C. and less than or equal to 710° C., greater than or equal to 700° C. and less than or equal to 710° C., greater than or equal to 680° C. and less than or equal to 700° C., greater than or equal to 690° C. and less than or equal to 700° C., or greater than or equal to 680° C. and less than or equal to 690° C. It should be understood that the above ranges include all subranges within the explicitly disclosed ranges.

In embodiments, the glass is held at the growth temperature for a duration that is greater than or equal to 1 minute to less than or equal to 240 minutes, greater than or equal to 30 minutes to less than or equal to 240 minutes, greater than or equal to 60 minutes to less than or equal to 240 minutes, greater than or equal to 90 minutes to less than or equal to 240 minutes, greater than or equal to 120 minutes to less than or equal to 240 minutes, greater than or equal to 150 minutes to less than or equal to 240 minutes, greater than or equal to 180 minutes to less than or equal to 240 minutes, greater than or equal to 210 minutes to less than or equal to 240 minutes, greater than or equal to 1 minute to less than or equal to 210 minutes, greater than or equal to 30 minutes to less than or equal to 210 minutes, greater than or equal to 60 minutes to less than or equal to 210 minutes, greater than or equal to 90 minutes to less than or equal to 210 minutes, greater than or equal to 120 minutes to less than or equal to 210 minutes, greater than or equal to 150 minutes to less than or equal to 210 minutes, greater than or equal to 180 minutes to less than or equal to 210 minutes, greater than or equal to 1 minute to less than or equal to 180 minutes, greater than or equal to 30 minutes to less than or equal to 180 minutes, greater than or equal to 60 minutes to less than or equal to 180 minutes, greater than or equal to 90 minutes to less than or equal to 180 minutes, greater than or equal to 120 minutes to less than or equal to 180 minutes, greater than or equal to 150 minutes to less than or equal to 180 minutes, greater than or equal to 1 minute to less than or equal to 150 minutes, greater than or equal to 30 minutes to less than or equal to 150 minutes, greater than or equal to 60 minutes to less than or equal to 150 minutes, greater than or equal to 90 minutes to less than or equal to 150 minutes, greater than or equal to 120 minutes to less than or equal to 150 minutes, greater than or equal to 1 minute to less than or equal to 120 minutes, greater than or equal to 30 minutes to less than or equal to 120 minutes, greater than or equal to 60 minutes to less than or equal to 120 minutes, greater than or equal to 90 minutes to less than or equal to 120 minutes, greater than or equal to 1 minute to less than or equal to 90 minutes, greater than or equal to 30 minutes to less than or equal to 90 minutes, greater than or equal to 60 minutes to less than or equal to 90 minutes, greater than or equal to 1 minute to less than or equal to 60 minutes, greater than or equal to 30 minutes to less than or equal to 60 minutes, or greater than or equal to 1 minute to less than or equal to 30 minutes. It should be understood that the above ranges include all subranges within the explicitly disclosed ranges. The growth stage transitions the nucleated precursor glass into a glass-ceramic material.

A precursor glass article as disclosed and described herein held at the nucleation temperature and growth temperature for the durations disclosed and described herein will form a glass-ceramic having a phase assemblage that is high in an amorphous glassy phase, petalite (LiAlSi₄O₁₀), and lithium disilicate (Li₂Si₂O₅). The glass-ceramic comprises less than 5 wt %, such as less than 3 wt %, of the sum of other crystalline phases (such as, but not limited to lithium metasilicate (Li₂SiO₃), virgilite (LiₓAlₓSi₃₋ₓO₆), cristabolite (SiO₂), Quartz (SiO₂), zirconia (ZrO₂), baddeleyite (ZrO₂), spodumene (LiAlSi₂O₆), and lithium phosphate (Li₃PO₄)). This phase assemblage provides a glass-ceramic that has low haze (high clarity) and improved mechanical properties compared to glass-ceramic articles previously available.

It is believed that the nucleation and growth temperatures and durations disclosed and described herein are the heat treatments that primarily result in the desired phase assemblage in the glass-ceramic material. Therefore, additional heat treatments may be included before the nucleation stage, between the nucleation stage and the growth stage, and after the growth stage without causing significant deviation in the phase assemblage of the glass-ceramic material. These additional heat treatments include isothermal holds, heating at specific heating schedules including a number of differing heating rates, and combinations thereof.

Accordingly, in embodiments, there may be one of more additional temperature holds between the nucleation temperature and the growth temperature. Thus, in embodiments, after maintaining the precursor glass at the nucleation temperature, the article may be heated to one or more intermediate temperatures (wherein the intermediate temperatures are in a range between the nucleation temperature and the growth temperature) and held at the one or more intermediate temperatures for a predetermined time (for example, between 1 minute and 240 minutes and all ranges and subranges there between) and then heated to the growth temperature.

In embodiments, the nucleation stage comprises an isothermal hold at a single nucleation temperature for a duration. However, in other embodiments, the nucleation stage includes heating the precursor glass at one or more heating rates through the nucleation temperature range described herein (i.e., from greater than or equal to 550° C. to less than or equal to 650° C.). Likewise, in embodiments, the growth stage comprises an isothermal hold at a single growth temperature for a duration. However, in other embodiments, the growth stage includes heating or cooling the nucleated precursor glass at one or more heating rates within the growth temperature range described herein (i.e., from greater than or equal to 680° C. to less than or equal to 800° C.).

According to embodiments, heating rates used to heat from room temperature to the nucleation temperature, within the nucleation stage, between the nucleation stage and the growth stage, within the growth stage, and after the growth stage is greater than or equal to 0.1° C./min and less than or equal to 50° C./min, greater than or equal to 5° C./min and less than or equal to 50° C./min, greater than or equal to 10° C./min and less than or equal to 50° C./min, greater than or equal to 15° C./min and less than or equal to 50° C./min, greater than or equal to 20° C./min and less than or equal to 50° C./min, greater than or equal to 25° C./min and less than or equal to 50° C./min, greater than or equal to 30° C./min and less than or equal to 50° C./min, greater than or equal to 35° C./min and less than or equal to 50° C./min, greater than or equal to 40° C./min and less than or equal to 50° C./min, greater than or equal to 45° C./min and less than or equal to 50° C./min, greater than or equal to 0.1° C./min and less than or equal to 45° C./min, greater than or equal to 5° C./min and less than or equal to 45° C./min, greater than or equal to 10° C./min and less than or equal to 45° C./min, greater than or equal to 15° C./min and less than or equal to 45° C./min, greater than or equal to 20° C./min and less than or equal to 45° C./min, greater than or equal to 25° C./min and less than or equal to 45° C./min, greater than or equal to 30° C./min and less than or equal to 45° C./min, greater than or equal to 35° C./min and less than or equal to 45° C./min, greater than or equal to 40° C./min and less than or equal to 45° C./min, greater than or equal to 0.1° C./min and less than or equal to 40° C./min, greater than or equal to 5° C./min and less than or equal to 40° C./min, greater than or equal to 10° C./min and less than or equal to 40° C./min, greater than or equal to 15° C./min and less than or equal to 40° C./min, greater than or equal to 20° C./min and less than or equal to 40° C./min, greater than or equal to 25° C./min and less than or equal to 40° C./min, greater than or equal to 30° C./min and less than or equal to 40° C./min, greater than or equal to 35° C./min and less than or equal to 40° C./min, greater than or equal to 0.1° C./min and less than or equal to 35° C./min, greater than or equal to 5° C./min and less than or equal to 35° C./min, greater than or equal to 10° C./min and less than or equal to 35° C./min, greater than or equal to 15° C./min and less than or equal to 35° C./min, greater than or equal to 20° C./min and less than or equal to 35° C./min, greater than or equal to 25° C./min and less than or equal to 35° C./min, greater than or equal to 30° C./min and less than or equal to 35° C./min, greater than or equal to 0.1° C./min and less than or equal to 30° C./min, greater than or equal to 5° C./min and less than or equal to 30° C./min, greater than or equal to 10° C./min and less than or equal to 30° C./min, greater than or equal to 15° C./min and less than or equal to 30° C./min, greater than or equal to 20° C./min and less than or equal to 30° C./min, greater than or equal to 25° C./min and less than or equal to 30° C./min, greater than or equal to 0.1° C./min and less than or equal to 25° C./min, greater than or equal to 5° C./min and less than or equal to 25° C./min, greater than or equal to 10° C./min and less than or equal to 25° C./min, greater than or equal to 15° C./min and less than or equal to 25° C./min, greater than or equal to 20° C./min and less than or equal to 25° C./min, greater than or equal to 0.1° C./min and less than or equal to 20° C./min, greater than or equal to 5° C./min and less than or equal to 20° C./min, greater than or equal to 10° C./min and less than or equal to 20° C./min, greater than or equal to 15° C./min and less than or equal to 20° C./min, greater than or equal to 0.1° C./min and less than or equal to 15° C./min, greater than or equal to 5° C./min and less than or equal to 15° C./min, greater than or equal to 10° C./min and less than or equal to 15° C./min, greater than or equal to 0.1° C./min and less than or equal to 10° C./min, greater than or equal to 5° C./min and less than or equal to 10° C./min, or greater than or equal to 0.1° C./min and less than or equal to 5° C./min. It should be understood that the above ranges include all subranges within the explicitly disclosed ranges. Such heating rates allow the proper amount of nucleation and crystal growth without damaging the glass-ceramic article. If heating is done to quickly, the material may be damaged. However, if heating is done too slowly, proper nucleation and growth may not occur.

In embodiments, the glass-ceramic article is cooled after being held at the growth temperature. In embodiments, the glass-ceramic article may be cooled to room temperature in a single stage at a constant cooling rate, in two stages each with a different cooling rate, or in three or more stages each with a different cooling rate. In embodiments, the glass-ceramic articles are cooled at a controlled rate from the growth temperature in order to minimize temperature gradients across the articles as well as minimize residual stress across the articles. Temperature gradients and differences in residual stress may lead to the articles warping during cooling. Thus, controlling the cooling to control the temperature gradients and residuals stresses may also minimize warpage of the glass-ceramic articles.

Upon performing the above heat treatments to the precursor glass, the resultant glass-ceramic has a phase assemblage where lithium disilicate and petalite are the crystalline phases with the highest weight percentages. In embodiments, lithium disilicate and petalite are present in about the same amount by weight percent and comprise greater than or equal to 75 wt % and less than or equal to 90 wt %, greater than or equal to 80 wt % and less than or equal to 90 wt %, greater than or equal to 85 wt % and less than or equal to 90 wt %, greater than or equal to 75 wt % and less than or equal to 85 wt %, greater than or equal to 80 wt % and less than or equal to 85 wt %, or greater than or equal to 75 wt % and less than or equal to 80 wt %. It should be understood that the above ranges include all subranges within the explicitly disclosed ranges.

Lithium disilicate, Li₂Si₂O₅, is an orthorhombic crystal based on corrugated sheets of {Si₂O₅} tetrahedral arrays. The crystals are typically tabular or lath-like in shape, with pronounced cleavage planes. Glass-ceramics based on lithium disilicate offer highly desirable mechanical properties, including high body strength and fracture toughness, due to their microstructures of randomly-oriented interlocked crystals—a crystal structure that forces cracks to propagate through the material via tortuous paths around these crystals. In embodiments, the weight percentage of the lithium disilicate crystalline phase in the glass-ceramic compositions is greater than or equal to 30 wt % and less than or equal to 50 wt %, greater than or equal to 32 wt % and less than or equal to 50 wt %, greater than or equal to 35 wt % and less than or equal to 50 wt %, greater than or equal to 37 wt % and less than or equal to 50 wt %, greater than or equal to 40 wt % and less than or equal to 50 wt %, greater than or equal to 42 wt % and less than or equal to 50 wt %, greater than or equal to 45 wt % and less than or equal to 50 wt %, greater than or equal to 47 wt % and less than or equal to 50 wt %, greater than or equal to 30 wt % and less than or equal to 47 wt %, greater than or equal to 32 wt % and less than or equal to 47 wt %, greater than or equal to 35 wt % and less than or equal to 47 wt %, greater than or equal to 37 wt % and less than or equal to 47 wt %, greater than or equal to 40 wt % and less than or equal to 47 wt %, greater than or equal to 42 wt % and less than or equal to 47 wt %, greater than or equal to 45 wt % and less than or equal to 47 wt %, greater than or equal to 30 wt % and less than or equal to 45 wt %, greater than or equal to 32 wt % and less than or equal to 45 wt %, greater than or equal to 35 wt % and less than or equal to 45 wt %, greater than or equal to 37 wt % and less than or equal to 45 wt %, greater than or equal to 40 wt % and less than or equal to 45 wt %, greater than or equal to 42 wt % and less than or equal to 45 wt %, greater than or equal to 30 wt % and less than or equal to 42 wt %, greater than or equal to 32 wt % and less than or equal to 42 wt %, greater than or equal to 35 wt % and less than or equal to 42 wt %, greater than or equal to 37 wt % and less than or equal to 42 wt %, greater than or equal to 40 wt % and less than or equal to 42 wt %, greater than or equal to 30 wt % and less than or equal to 40 wt %, greater than or equal to 32 wt % and less than or equal to 40 wt %, greater than or equal to 35 wt % and less than or equal to 40 wt %, greater than or equal to 37 wt % and less than or equal to 40 wt %, greater than or equal to 30 wt % and less than or equal to 37 wt %, greater than or equal to 32 wt % and less than or equal to 37 wt %, greater than or equal to 35 wt % and less than or equal to 37 wt %, greater than or equal to 30 wt % and less than or equal to 35 wt %, greater than or equal to 32 wt % and less than or equal to 35 wt %, or greater than or equal to 30 wt % and less than or equal to 32 wt %. It should be understood that the above ranges include all subranges within the explicitly disclosed ranges. In embodiments, the glass-ceramic has 30, 31, 32, 33, 34, 35, 36, 37, 38, 39, 40, 41, 42, 43, 44, 45, 46, 47, 48, 49, or 50 wt % lithium disilicate crystalline phase.

Petalite is a monoclinic crystal possessing a three-dimensional framework structure with a layered structure having folded Si₂O₅ layers linked by Li and Al tetrahedral. The Li is in tetrahedral coordination with oxygen. The mineral petalite is a lithium source and is used as a low thermal expansion phase to improve the thermal downshock resistance of glass-ceramic or ceramic parts. Moreover, glass-ceramic articles based on the petalite phase can be chemically strengthened in a salt bath, during which Na⁺ (and/or K+) replaces Li⁺ in the petalite structure, which causes surface compression and strengthening. In embodiments, the weight percentage of the petalite crystalline phase in the glass-ceramic compositions is greater than or equal to 30 wt % and less than or equal to 50 wt %, greater than or equal to 32 wt % and less than or equal to 50 wt %, greater than or equal to 35 wt % and less than or equal to 50 wt %, greater than or equal to 37 wt % and less than or equal to 50 wt %, greater than or equal to 40 wt % and less than or equal to 50 wt %, greater than or equal to 42 wt % and less than or equal to 50 wt %, greater than or equal to 45 wt % and less than or equal to 50 wt %, greater than or equal to 47 wt % and less than or equal to 50 wt %, greater than or equal to 30 wt % and less than or equal to 47 wt %, greater than or equal to 32 wt % and less than or equal to 47 wt %, greater than or equal to 35 wt % and less than or equal to 47 wt %, greater than or equal to 37 wt % and less than or equal to 47 wt %, greater than or equal to 40 wt % and less than or equal to 47 wt %, greater than or equal to 42 wt % and less than or equal to 47 wt %, greater than or equal to 45 wt % and less than or equal to 47 wt %, greater than or equal to 30 wt % and less than or equal to 45 wt %, greater than or equal to 32 wt % and less than or equal to 45 wt %, greater than or equal to 35 wt % and less than or equal to 45 wt %, greater than or equal to 37 wt % and less than or equal to 45 wt %, greater than or equal to 40 wt % and less than or equal to 45 wt %, greater than or equal to 42 wt % and less than or equal to 45 wt %, greater than or equal to 30 wt % and less than or equal to 42 wt %, greater than or equal to 32 wt % and less than or equal to 42 wt %, greater than or equal to 35 wt % and less than or equal to 42 wt %, greater than or equal to 37 wt % and less than or equal to 42 wt %, greater than or equal to 40 wt % and less than or equal to 42 wt %, greater than or equal to 30 wt % and less than or equal to 40 wt %, greater than or equal to 32 wt % and less than or equal to 40 wt %, greater than or equal to 35 wt % and less than or equal to 40 wt %, greater than or equal to 37 wt % and less than or equal to 40 wt %, greater than or equal to 30 wt % and less than or equal to 37 wt %, greater than or equal to 32 wt % and less than or equal to 37 wt %, greater than or equal to 35 wt % and less than or equal to 37 wt %, greater than or equal to 30 wt % and less than or equal to 35 wt %, greater than or equal to 32 wt % and less than or equal to 35 wt %, or greater than or equal to 30 wt % and less than or equal to 32 wt %. It should be understood that the above ranges include all subranges within the explicitly disclosed ranges. In embodiments, the glass-ceramic has 30, 31, 32, 33, 34, 35, 36, 37, 38, 39, 40, 41, 42, 43, 44, 45, 46, 47, 48, 49, or 50 wt % petalite crystalline phase.

As mentioned hereinabove, in embodiments the glass-ceramic comprises about the same amount of lithium disilicate and petalite, by weight percentage. In embodiments, a weight ratio of lithium disilicate to petalite in the glass-ceramic is greater than or equal to 0.5 and less than or equal to 1.5, greater than or equal to 0.6 and less than or equal to 1.5, greater than or equal to 0.7 and less than or equal to 1.5, greater than or equal to 0.8 and less than or equal to 1.5, greater than or equal to 0.9 and less than or equal to 1.5, greater than or equal to 1.0 and less than or equal to 1.5, greater than or equal to 1.1 and less than or equal to 1.5, greater than or equal to 1.2 and less than or equal to 1.5, greater than or equal to 1.3 and less than or equal to 1.5, greater than or equal to 1.4 and less than or equal to 1.5, greater than or equal to 0.5 and less than or equal to 1.4, greater than or equal to 0.6 and less than or equal to 1.4, greater than or equal to 0.7 and less than or equal to 1.4, greater than or equal to 0.8 and less than or equal to 1.4, greater than or equal to 0.9 and less than or equal to 1.4, greater than or equal to 1.0 and less than or equal to 1.4, greater than or equal to 1.1 and less than or equal to 1.4, greater than or equal to 1.2 and less than or equal to 1.4, greater than or equal to 1.3 and less than or equal to 1.4, greater than or equal to 0.5 and less than or equal to 1.3, greater than or equal to 0.6 and less than or equal to 1.3, greater than or equal to 0.7 and less than or equal to 1.3, greater than or equal to 0.8 and less than or equal to 1.3, greater than or equal to 0.9 and less than or equal to 1.3, greater than or equal to 1.0 and less than or equal to 1.3, greater than or equal to 1.1 and less than or equal to 1.3, greater than or equal to 1.2 and less than or equal to 1.3, greater than or equal to 0.5 and less than or equal to 1.2, greater than or equal to 0.6 and less than or equal to 1.2, greater than or equal to 0.7 and less than or equal to 1.2, greater than or equal to 0.8 and less than or equal to 1.2, greater than or equal to 0.9 and less than or equal to 1.2, greater than or equal to 1.0 and less than or equal to 1.2, greater than or equal to 1.1 and less than or equal to 1.2, greater than or equal to 0.5 and less than or equal to 1.1, greater than or equal to 0.6 and less than or equal to 1.1, greater than or equal to 0.7 and less than or equal to 1.1, greater than or equal to 0.8 and less than or equal to 1.1, greater than or equal to 0.9 and less than or equal to 1.1, greater than or equal to 1.0 and less than or equal to 1.1, greater than or equal to 0.5 and less than or equal to 1.0, greater than or equal to 0.6 and less than or equal to 1.0, greater than or equal to 0.7 and less than or equal to 1.0, greater than or equal to 0.8 and less than or equal to 1.0, greater than or equal to 0.9 and less than or equal to 1.0, greater than or equal to 0.5 and less than or equal to 0.9, greater than or equal to 0.6 and less than or equal to 0.9, greater than or equal to 0.7 and less than or equal to 0.9, greater than or equal to 0.8 and less than or equal to 0.9, greater than or equal to 0.5 and less than or equal to 0.8, greater than or equal to 0.6 and less than or equal to 0.8, greater than or equal to 0.7 and less than or equal to 0.8, greater than or equal to 0.5 and less than or equal to 0.7, greater than or equal to 0.6 and less than or equal to 0.7, or greater than or equal to 0.5 and less than or equal to 0.6. It should be understood that the above ranges include all subranges within the explicitly disclosed ranges.

In embodiments, the glass-ceramic has a residual amorphous glass content that is greater than or equal to 5 wt % and less than or equal to 20 wt %, greater than or equal to 7 wt % and less than or equal to 20 wt %, greater than or equal to 10 wt % and less than or equal to 20 wt %, greater than or equal to 12 wt % and less than or equal to 20 wt %, greater than or equal to 15 wt % and less than or equal to 20 wt %, greater than or equal to 17 wt % and less than or equal to 20 wt %, greater than or equal to 5 wt % and less than or equal to 17 wt %, greater than or equal to 7 wt % and less than or equal to 17 wt %, greater than or equal to 10 wt % and less than or equal to 17 wt %, greater than or equal to 12 wt % and less than or equal to 17 wt %, greater than or equal to 15 wt % and less than or equal to 17 wt %, greater than or equal to 5 wt % and less than or equal to 15 wt %, greater than or equal to 7 wt % and less than or equal to 15 wt %, greater than or equal to 10 wt % and less than or equal to 15 wt %, greater than or equal to 12 wt % and less than or equal to 15 wt %, greater than or equal to 5 wt % and less than or equal to 12 wt %, greater than or equal to 7 wt % and less than or equal to 12 wt %, greater than or equal to 10 wt % and less than or equal to 12 wt %, greater than or equal to 5 wt % and less than or equal to 10 wt %, greater than or equal to 7 wt % and less than or equal to 10 wt %, or greater than or equal to 5 wt % and less than or equal to 7 wt %. It should be understood that the above ranges include all subranges within the explicitly disclosed ranges. In embodiments the residual amorphous glass content can be 20, 19, 18, 17, 16, 15, 14, 13, 12, 11, 10, 9, 8, 7, 6, or 5 wt %.

As previously disclosed herein, in embodiments, the glass-ceramic comprises less than 5 wt %, such as less than 3 wt %, of the sum of crystalline phases other than lithium disilicate and petalite, such as, but not limited to lithium metasilicate (Li₂SiO₃), virgilite (LixAlxSi₃₋ₓO₆), cristabolite (SiO₂), Quartz (SiO₂), zirconia (ZrO₂), baddeleyite (ZrO₂), spodumene (LiAlSi₂O₆), and lithium phosphate (Li₃PO₄). In embodiments, the glass-ceramic comprises less than 2 wt % of the sum of crystalline phases other than lithium disilicate and petalite, or less than 1 wt % of the sum of crystalline phases other than lithium disilicate and petalite.

The crystal phase assemblage described herein limits the mismatch in indices between the crystals and the residual amorphous glass, which reduces scatter and resulting haze of the glass-ceramic.

The grain size of the crystals in the crystalline phases is a factor that affects the transparency of the glass-ceramic. In embodiments, the grains have a longest dimension in a range from about 5 nm to about 150 nm, about 5 nm to about 125 nm, about 5 nm to about 100 nm, about 5 nm to about 75 nm, about 5 nm to about 50 nm, about 25 nm to about 150 nm, about 25 nm to about 125 nm, about 25 nm to about 100 nm, about 25 nm to about 75 nm, about 50 nm to about 150 nm, about 50 nm to about 125 nm, about 50 nm to about 100 nm, and all ranges and subranges there between. In embodiments, the longest dimension of the grains is less than 150 nm, less than 125 nm, less than 100 nm, less than 75 nm, less than 50 nm, or less than 25 nm. The longest dimension of the grains is measured using a scanning electron microscope (SEM).

In embodiments, the glass-ceramic article has high transparency and low haze and is suitable for use as a cover glass for a mobile electronic device. In embodiments, the glass-ceramic article is transparent in that it has an average transmittance of 85% or greater, 86% or greater, 87% or greater, 88% or greater, 89% or greater, 90% or greater, 91% or greater, 92% or greater, 93% or greater (including surface reflection losses) of light over the wavelength range from 450 nm to 600 nm for a glass-ceramic article having a thickness of 1 mm. In other embodiments, glass-ceramic may be translucent over the wavelength range from 450 nm to 600 nm. In embodiments a translucent glass-ceramic can have an average transmittance in a range from about 20% to less than about 85% of light over the wavelength range of about 450 nm to about 800 nm for a glass-ceramic article having a thickness of 1 mm. In embodiments, the glass-ceramic article has a haze of less or equal to 0.15, 0.14, 0.13, 0.12, 0.11, 0.10, 0.09, 0.08, 0.07, 0.06, or 0.05 as measured on a glass-ceramic article having a thickness of 0.6 mm.

### Chemical Strengthening

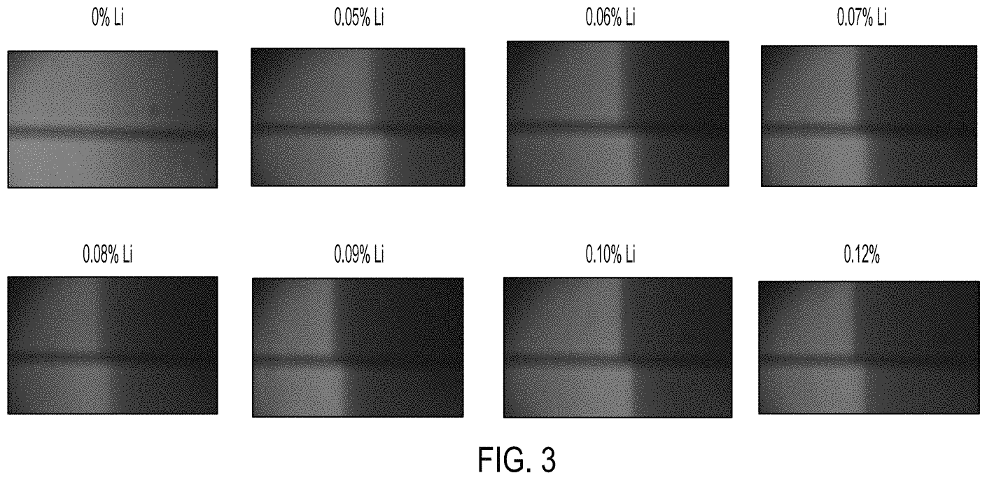

In embodiments, glass-ceramic articles may be strengthened to have a compressive stress layer on one or more surface thereof. With reference now to FIG. 2, an exemplary cross-sectional side view of a strengthened glass-ceramic article 100 is depicted having a first surface 102 and an opposing second surface 104 separated by a thickness (t). In embodiments, strengthened glass-ceramic article 100 has been ion exchanged and has a compressive stress (CS) layer 106 (or first region) extending from first surface 102 to a depth of compression (DOC). In embodiments, as shown in FIG. 2, the glass-ceramic article 100 also has a compressive stress (CS) layer 108 extending from second surface 104 to a depth of compression DOC′.

In embodiments, the glass-ceramic article is capable of being chemically strengthened using one or more ion exchange techniques. In these embodiments, ion exchange can occur by subjecting one or more surfaces of such glass-ceramic article to one or more ion exchange mediums (for example molten salt baths), having a specific composition and temperature, for a specified time period to impart to the one or more surfaces with compressive stress layer(s). In embodiments, the ion exchange medium is a molten salt bath containing an ion (for example an alkali metal ion) that is larger than an ion (for example an alkali metal ion) present in the glass-ceramic article wherein the larger ion from the molten bath is exchanged with the smaller ion in the glass-ceramic article to impart a compressive stress in the glass-ceramic article, and thereby increases the strength of the glass-ceramic article.

In embodiments, a one step ion exchange process can be used and in other embodiments, a multi step ion exchange process can be used. In embodiments, for both one step and multi step ion exchange processes the ion exchange mediums (for example, molten baths) can include potassium nitrate (KNO₃) and sodium nitrate (NaNO₃) as primary components. The ion exchange mediums can, in embodiments, further comprise lithium nitrate (LiNO₃), sodium nitrite (NaNO₂), and silicic acid.

In embodiments, the ion exchange medium comprises greater than or equal to 50 wt % and less than or equal to 70 wt % KNO₃, greater than or equal to 55 wt % and less than or equal to 70 wt % KNO₃, greater than or equal to 60 wt % and less than or equal to 70 wt % KNO₃, greater than or equal to 65 wt % and less than or equal to 70 wt % KNO₃, greater than or equal to 50 wt % and less than or equal to 65 wt % KNO₃, greater than or equal to 55 wt % and less than or equal to 65 wt % KNO₃, greater than or equal to 60 wt % and less than or equal to 65 wt % KNO₃, greater than or equal to 50 wt % and less than or equal to 60 wt % KNO₃, greater than or equal to 55 wt % and less than or equal to 60 wt % KNO₃, or greater than or equal to 50 wt % and less than or equal to 55 wt % KNO₃. It should be understood that the above ranges include all subranges within the explicitly disclosed ranges.

In embodiments, the ion exchange medium comprises greater than or equal to 30 wt % and less than or equal to 50 wt % NaNO₃, greater than or equal to 35 wt % and less than or equal to 50 wt % NaNO₃, greater than or equal to 40 wt % and less than or equal to 50 wt % NaNO₃, greater than or equal to 45 wt % and less than or equal to 50 wt % NaNO₃, greater than or equal to 30 wt % and less than or equal to 45 wt % NaNO₃, greater than or equal to 35 wt % and less than or equal to 45 wt % NaNO₃, greater than or equal to 40 wt % and less than or equal to 45 wt % NaNO₃, greater than or equal to 30 wt % and less than or equal to 40 wt % NaNO₃, greater than or equal to 35 wt % and less than or equal to 40 wt % NaNO₃, or greater than or equal to 30 wt % and less than or equal to 35 wt % NaNO₃. It should be understood that the above ranges include all subranges within the explicitly disclosed ranges.

In embodiments, the ion exchange medium comprises greater than or equal to 0.05 wt % and less than or equal to 0.15 wt % LiNO₃, greater than or equal to 0.08 wt % and less than or equal to 0.15 wt % LiNO₃, greater than or equal to 0.10 wt % and less than or equal to 0.15 wt % LiNO₃, greater than or equal to 0.12 wt % and less than or equal to 0.15 wt % LiNO₃, greater than or equal to 0.05 wt % and less than or equal to 0.12 wt % LiNO₃, greater than or equal to 0.08 wt % and less than or equal to 0.12 wt % LiNO₃, greater than or equal to 0.10 wt % and less than or equal to 0.12 wt % LiNO₃, greater than or equal to 0.05 wt % and less than or equal to 0.10 wt % LiNO₃, greater than or equal to 0.08 wt % and less than or equal to 0.10 wt % LiNO₃, or greater than or equal to 0.05 wt % and less than or equal to 0.08 wt % LiNO₃. It should be understood that the above ranges include all subranges within the explicitly disclosed ranges.

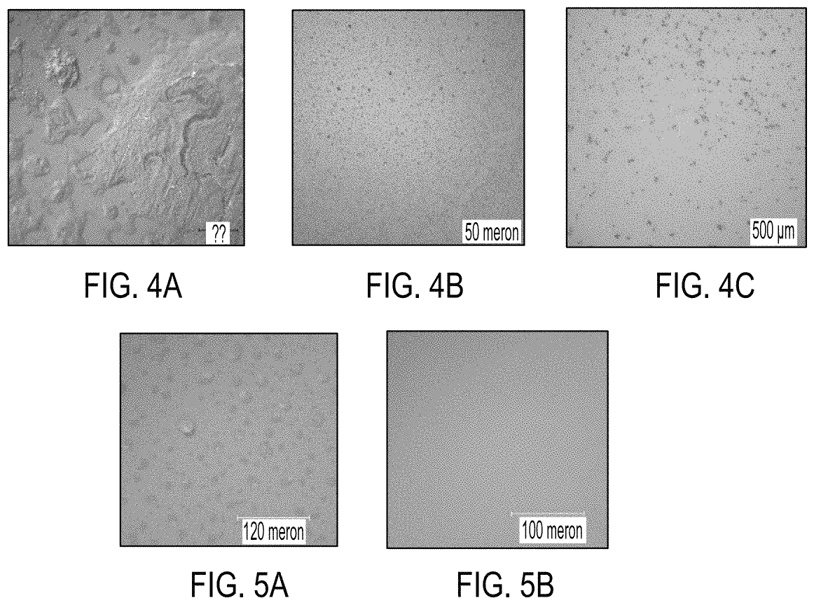

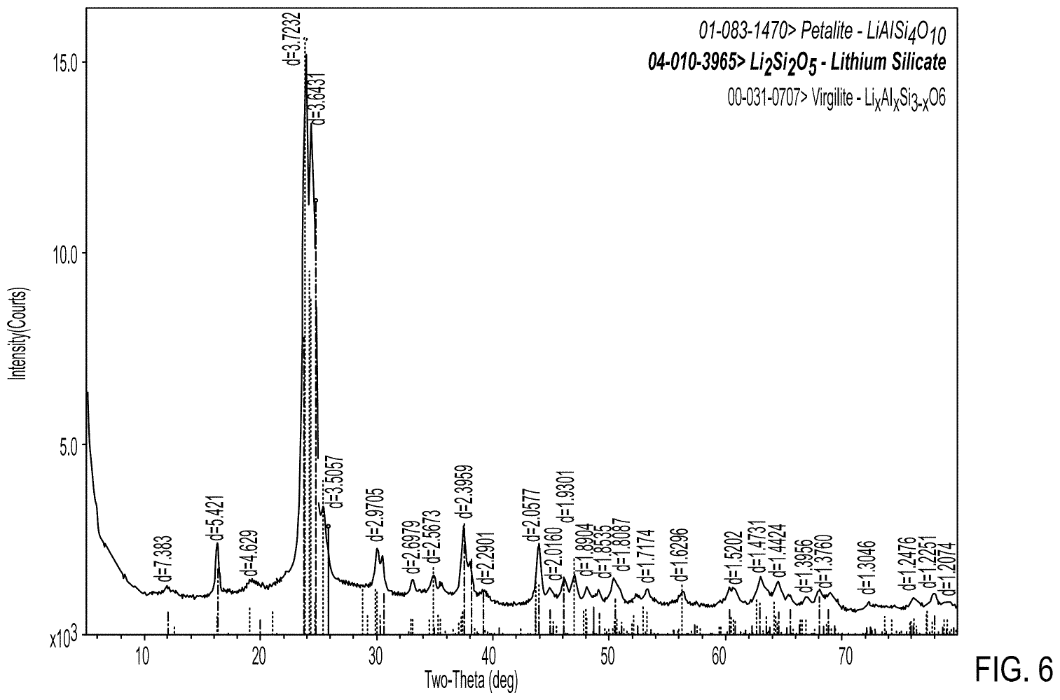

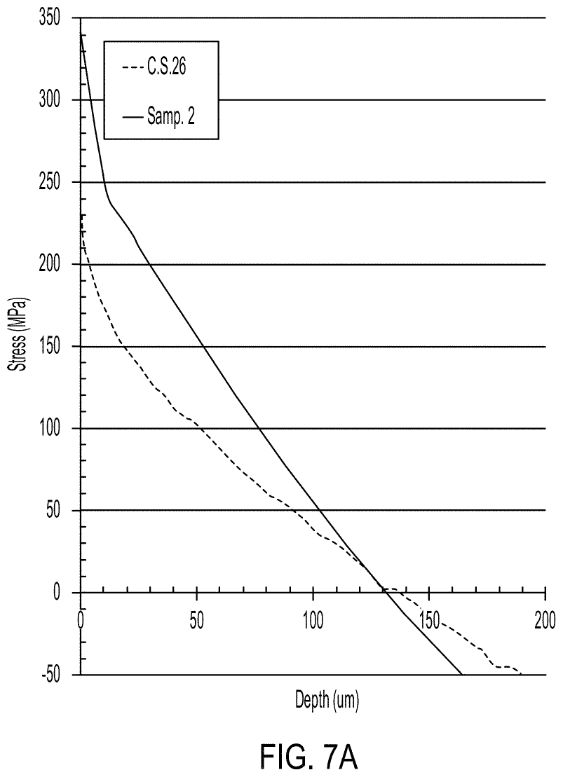

Including lithium in the ion exchange medium—by the addition of LiNO₃—may improve the corrosion resistance of glass-ceramics according to embodiments disclosed and described herein. FIG. 3 shows Fundamental Stress Meter (FSM) images of glass-ceramics having the composition according to Table 1 below and ion exchanged in a ˜60 wt % KNO₃/˜40 wt % NaNO₃+X wt % LiNO₃ molten salt bath at 530° C. for 4 hours, where “X” is 0 wt % Li, 0.05 wt % Li, 0.06 wt % Li, 0.07 wt % Li, 0.08 wt % Li, 0.09 wt % Li, 0.10 wt % Li, or 0.12 wt % Li as depicted in FIGS. 3A to 5B. As shown in FIG. 3, a transition begins at about 0.05 wt % Li, and a sharp transition is present at lithium contents greater than or equal to 0.08 wt %. This transition shown in the FSM images of FIG. 3 show a link to corrosion resistance. FIGS. 3A-3C show corrosion on the surface of a glass-ceramic prepared according to embodiments disclosed and described herein and exposed to 500 hours at 85° C. and 85% relative humidity. With reference now to FIG. 4A, similar glass-ceramics that are strengthened in an ion exchange medium that does not include Li has heavy sodium carbonate corrosion. However, adding lithium to the ion exchange medium appears to negate the sodium carbonate corrosion. FIG. 4B shows a glass-ceramic treated with an ion exchange medium having 0.06 wt % Li and having no sodium carbonate corrosion, and FIG. 4C shows a glass-ceramic treated with an ion exchange medium having 0.08 wt % lithium and having no sodium carbonate corrosion. In contrast, glass-ceramics shown in FIG. 5A and FIG. 5B, which are not prepared according to the embodiments disclosed and described herein, show sodium carbonate corrosion when exposed to 500 hours at 85° C. and 85% relative humidity even when they are treated with an ion exchange medium having 0.05 wt % Li (FIG. 5A) and 0.65 wt % Li (FIG. 5B). Without being bound by any particular theory, it is believed that glass-ceramics prepared according to embodiments disclosed and described herein and treated in an ion exchange medium having lithium can achieve higher sodium content on the surface at maximum central tension than conventional glass-ceramics. However, this high sodium content does not cause formation of an amorphous layer—which can become present in conventional glass-ceramics—that can decompose surface crystals and cause corrosion.

In embodiments, the ion exchange medium comprises greater than or equal to 0.40 wt % and less than or equal to 0.60 wt % NaNO₂, greater than or equal to 0.45 wt % and less than or equal to 0.60 wt % NaNO₂, greater than or equal to 0.50 wt % and less than or equal to 0.60 wt % NaNO₂, greater than or equal to 0.55 wt % and less than or equal to 0.60 wt % NaNO₂, greater than or equal to 0.40 wt % and less than or equal to 0.55 wt % NaNO₂, greater than or equal to 0.45 wt % and less than or equal to 0.55 wt % NaNO₂, greater than or equal to 0.50 wt % and less than or equal to 0.55 wt % NaNO₂, greater than or equal to 0.40 wt % and less than or equal to 0.50 wt % NaNO₂, greater than or equal to 0.45 wt % and less than or equal to 0.50 wt % NaNO₂, or greater than or equal to 0.40 wt % and less than or equal to 0.45 wt %. It should be understood that the above ranges include all subranges within the explicitly disclosed ranges.

In embodiments, the ion exchange medium comprises greater than or equal to 0.40 wt % and less than or equal to 0.60 wt % silicic acid, greater than or equal to 0.45 wt % and less than or equal to 0.60 wt % silicic acid, greater than or equal to 0.50 wt % and less than or equal to 0.60 wt % silicic acid, greater than or equal to 0.55 wt % and less than or equal to 0.60 wt % silicic acid, greater than or equal to 0.40 wt % and less than or equal to 0.55 wt % silicic acid, greater than or equal to 0.45 wt % and less than or equal to 0.55 wt % silicic acid, greater than or equal to 0.50 wt % and less than or equal to 0.55 wt % silicic acid, greater than or equal to 0.40 wt % and less than or equal to 0.50 wt % silicic acid, greater than or equal to 0.45 wt % and less than or equal to 0.50 wt % silicic acid, or greater than or equal to 0.40 wt % and less than or equal to 0.45 wt %. It should be understood that the above ranges include all subranges within the explicitly disclosed ranges.

The temperature of the ion exchange medium is, in embodiments, greater than or equal to 450° C. and less than or equal to 550° C., greater than or equal to 475° C. and less than or equal to 550° C., greater than or equal to 500° C. and less than or equal to 550° C., greater than or equal to 525° C. and less than or equal to 550° C., greater than or equal to 530° C. and less than or equal to 550° C., greater than or equal to 450° C. and less than or equal to 530° C., greater than or equal to 475° C. and less than or equal to 530° C., greater than or equal to 500° C. and less than or equal to 530° C., greater than or equal to 525° C. and less than or equal to 530° C., greater than or equal to 450° C. and less than or equal to 525° C., greater than or equal to 475° C. and less than or equal to 525° C., greater than or equal to 500° C. and less than or equal to 525° C., greater than or equal to 450° C. and less than or equal to 500° C., greater than or equal to 475° C. and less than or equal to 500° C., or greater than or equal to 450° C. and less than or equal to 475° C. It should be understood that the above ranges include all subranges within the explicitly disclosed ranges.

According to embodiments, the glass-ceramic article is contacted with the ion exchange medium for a duration that is greater than or equal to 1 hour and less than or equal to 16 hours, greater than or equal to 2 hour and less than or equal to 16 hours, greater than or equal to 4 hour and less than or equal to 16 hours, greater than or equal to 6 hour and less than or equal to 16 hours, greater than or equal to 8 hour and less than or equal to 16 hours, greater than or equal to 10 hour and less than or equal to 16 hours, greater than or equal to 12 hour and less than or equal to 16 hours, greater than or equal to 14 hour and less than or equal to 16 hours, greater than or equal to 1 hour and less than or equal to 14 hours, greater than or equal to 2 hour and less than or equal to 14 hours, greater than or equal to 4 hour and less than or equal to 14 hours, greater than or equal to 6 hour and less than or equal to 14 hours, greater than or equal to 8 hour and less than or equal to 14 hours, greater than or equal to 10 hour and less than or equal to 14 hours, greater than or equal to 12 hour and less than or equal to 14 hours, greater than or equal to 1 hour and less than or equal to 12 hours, greater than or equal to 2 hour and less than or equal to 12 hours, greater than or equal to 4 hour and less than or equal to 12 hours, greater than or equal to 6 hour and less than or equal to 12 hours, greater than or equal to 8 hour and less than or equal to 12 hours, greater than or equal to 10 hour and less than or equal to 12 hours, greater than or equal to 1 hour and less than or equal to 10 hours, greater than or equal to 2 hour and less than or equal to 10 hours, greater than or equal to 4 hour and less than or equal to 10 hours, greater than or equal to 6 hour and less than or equal to 10 hours, greater than or equal to 8 hour and less than or equal to 10 hours, greater than or equal to 1 hour and less than or equal to 8 hours, greater than or equal to 2 hour and less than or equal to 8 hours, greater than or equal to 4 hour and less than or equal to 8 hours, greater than or equal to 6 hour and less than or equal to 8 hours, greater than or equal to 1 hour and less than or equal to 6 hours, greater than or equal to 2 hour and less than or equal to 6 hours, greater than or equal to 4 hour and less than or equal to 6 hours, greater than or equal to 1 hour and less than or equal to 4 hours, greater than or equal to 2 hour and less than or equal to 4 hours, or greater than or equal to 1 hour and less than or equal to 2 hours. It should be understood that the above ranges include all subranges within the explicitly disclosed ranges.

After an ion exchange process is performed, it should be understood that a composition at the surface of the glass-ceramic may be different than the composition of the as-formed glass-ceramic (i.e., the glass-ceramic before it undergoes an ion exchange process). This results from one type of alkali metal ion in the as-formed glass-ceramic, such as, for example Li⁺ or Na⁺, being replaced with larger alkali metal ions, such as, for example Na⁺ or K⁺, respectively. However, the composition of the glass-ceramic at or near the center of the depth of the glass-ceramic article will, in embodiments, still have the composition of the as-formed glass-ceramic. As utilized herein, the center of the glass article refers to any location in the glass article that is a distance of at least 0.5 t from every surface thereof, where t is the thickness of the glass article.

### Mechanical Properties of Glass-Ceramic Articles

The mechanic properties of glass-ceramic articles disclosed herein are tested on strengthened glass-ceramic articles unless otherwise indicated. By forming a glass-ceramic having a composition as disclosed and described herein, using the heat treatments and chemical strengthening as disclosed and described herein, glass-ceramics with phase assemblages that provide low haze and good mechanical properties (as described in detail below) can be achieved. Even though described in separate paragraphs below, the various mechanical properties are present in combination in glass-ceramics of embodiments. The balance of these mechanical properties provide a durable, robust glass-ceramic that is difficult to achieve without sacrificing other mechanical properties. For instance, and as an example only, achieving high compressive stress alone is possible, but achieving high compressive stress and central tension can be more difficult.

In embodiments, DOC and DOC′ are individually greater than or equal to 0.15 t and less than or equal to 0.25 t, greater than or equal to 0.16 t and less than or equal to 0.25 t, greater than or equal to 0.17 and less than or equal to 0.25 t, greater than or equal to 0.18 t and less than or equal to 0.25 t, greater than or equal to 0.19 t and less than or equal to 0.25 t, greater than or equal to 0.20 t and less than or equal to 0.25 t, greater than or equal to 0.21 t and less than or equal to 0.25 t, greater than or equal to 0.22 t and less than or equal to 0.25 t, greater than or equal to 0.23 t and less than or equal to 0.25 t, greater than or equal to 0.24 t and less than or equal to 0.25 t, greater than or equal to 0.15 t and less than or equal to 0.24 t, greater than or equal to 0.16 t and less than or equal to 0.24 t, greater than or equal to 0.17 and less than or equal to 0.24 t, greater than or equal to 0.18 t and less than or equal to 0.24 t, greater than or equal to 0.19 t and less than or equal to 0.24 t, greater than or equal to 0.20 t and less than or equal to 0.24 t, greater than or equal to 0.21 t and less than or equal to 0.24 t, greater than or equal to 0.22 t and less than or equal to 0.24 t, greater than or equal to 0.23 t and less than or equal to 0.24 t, greater than or equal to 0.15 t and less than or equal to 0.23 t, greater than or equal to 0.16 t and less than or equal to 0.23 t, greater than or equal to 0.17 and less than or equal to 0.23 t, greater than or equal to 0.18 t and less than or equal to 0.23 t, greater than or equal to 0.19 t and less than or equal to 0.23 t, greater than or equal to 0.20 t and less than or equal to 0.23 t, greater than or equal to 0.21 t and less than or equal to 0.23 t, greater than or equal to 0.22 t and less than or equal to 0.23 t, greater than or equal to 0.15 t and less than or equal to 0.22 t, greater than or equal to 0.16 t and less than or equal to 0.22 t, greater than or equal to 0.17 and less than or equal to 0.22 t, greater than or equal to 0.18 t and less than or equal to 0.22 t, greater than or equal to 0.19 t and less than or equal to 0.22 t, greater than or equal to 0.20 t and less than or equal to 0.22 t, greater than or equal to 0.21 t and less than or equal to 0.22 t, greater than or equal to 0.15 t and less than or equal to 0.21 t, greater than or equal to 0.16 t and less than or equal to 0.21 t, greater than or equal to 0.17 and less than or equal to 0.21 t, greater than or equal to 0.18 t and less than or equal to 0.21 t, greater than or equal to 0.19 t and less than or equal to 0.21 t, greater than or equal to 0.20 t and less than or equal to 0.21 t, greater than or equal to 0.15 t and less than or equal to 0.20 t, greater than or equal to 0.16 t and less than or equal to 0.20 t, greater than or equal to 0.17 and less than or equal to 0.20 t, greater than or equal to 0.18 t and less than or equal to 0.20 t, greater than or equal to 0.19 t and less than or equal to 0.20 t, greater than or equal to 0.15 t and less than or equal to 0.19 t, greater than or equal to 0.16 t and less than or equal to 0.19 t, greater than or equal to 0.17 and less than or equal to 0.19 t, greater than or equal to 0.18 t and less than or equal to 0.19 t, greater than or equal to 0.15 t and less than or equal to 0.18 t, greater than or equal to 0.16 t and less than or equal to 0.18 t, greater than or equal to 0.17 and less than or equal to 0.18 t, greater than or equal to 0.15 t and less than or equal to 0.17 t, greater than or equal to 0.16 t and less than or equal to 0.17 t, or greater than or equal to 0.15 t and less than or equal to 0.16 t.

There is also a central tension region 110 under tensile stress in between DOC and DOC′. Accordingly, stress transitions from compressive stress to tensile stress at DOC and DOC′, which are described hereinabove, measured from a surface toward a centerline of the strengthened glass-ceramic article.

In embodiments, the glass-ceramic articles may have a compressive stress (CS) of greater than or equal to 200 MPa and less than or equal to 400 MPa, such as greater than or equal to 225 MPa and less than or equal to 400 MPa, greater than or equal to 250 MPa and less than or equal to 400 MPa, greater than or equal to 275 MPa and less than or equal to 400 MPa, greater than or equal to 300 MPa and less than or equal to 400 MPa, greater than or equal to 325 MPa and less than or equal to 400 MPa, greater than or equal to 350 MPa and less than or equal to 400 MPa, greater than or equal to 375 MPa and less than or equal to 400 MPa, greater than or equal to 200 MPa and less than or equal to 375 MPa, greater than or equal to 225 MPa and less than or equal to 375 MPa, greater than or equal to 250 MPa and less than or equal to 375 MPa, greater than or equal to 275 MPa and less than or equal to 375 MPa, greater than or equal to 300 MPa and less than or equal to 375 MPa, greater than or equal to 325 MPa and less than or equal to 375 MPa, greater than or equal to 350 MPa and less than or equal to 375 MPa, greater than or equal to 200 MPa and less than or equal to 350 MPa, greater than or equal to 225 MPa and less than or equal to 350 MPa, greater than or equal to 250 MPa and less than or equal to 350 MPa, greater than or equal to 275 MPa and less than or equal to 350 MPa, greater than or equal to 300 MPa and less than or equal to 350 MPa, greater than or equal to 325 MPa and less than or equal to 350 MPa, greater than or equal to 200 MPa and less than or equal to 325 MPa, greater than or equal to 225 MPa and less than or equal to 325 MPa, greater than or equal to 250 MPa and less than or equal to 325 MPa, greater than or equal to 275 MPa and less than or equal to 325 MPa, greater than or equal to 300 MPa and less than or equal to 325 MPa, greater than or equal to 200 MPa and less than or equal to 300 MPa, greater than or equal to 225 MPa and less than or equal to 300 MPa, greater than or equal to 250 MPa and less than or equal to 300 MPa, greater than or equal to 275 MPa and less than or equal to 300 MPa, greater than or equal to 200 MPa and less than or equal to 275 MPa, greater than or equal to 225 MPa and less than or equal to 275 MPa, greater than or equal to 250 MPa and less than or equal to 275 MPa, greater than or equal to 200 MPa and less than or equal to 250 MPa, greater than or equal to 225 MPa and less than or equal to 250 MPa, or greater than or equal to 200 MPa and less than or equal to 225 MPa. It should be understood that the above ranges include all subranges within the explicitly disclosed ranges.

In embodiments, the maximum central tension (CT) is greater than or equal to 100 MPa and less than or equal to 170 MPa, such as greater than or equal to 110 MPa and less than or equal to 170 MPa, greater than or equal to 120 MPa and less than or equal to 170 MPa, greater than or equal to 130 MPa and less than or equal to 170 MPa, greater than or equal to 140 MPa and less than or equal to 170 MPa, greater than or equal to 150 MPa and less than or equal to 170 MPa, greater than or equal to 160 MPa and less than or equal to 170 MPa, greater than or equal to 100 MPa and less than or equal to 160 MPa, greater than or equal to 110 MPa and less than or equal to 160 MPa, greater than or equal to 120 MPa and less than or equal to 160 MPa, greater than or equal to 130 MPa and less than or equal to 160 MPa, greater than or equal to 140 MPa and less than or equal to 160 MPa, greater than or equal to 150 MPa and less than or equal to 160 MPa, greater than or equal to 100 MPa and less than or equal to 150 MPa, greater than or equal to 110 MPa and less than or equal to 150 MPa, greater than or equal to 120 MPa and less than or equal to 150 MPa, greater than or equal to 130 MPa and less than or equal to 150 MPa, greater than or equal to 140 MPa and less than or equal to 150 MPa, greater than or equal to 100 MPa and less than or equal to 140 MPa, greater than or equal to 110 MPa and less than or equal to 140 MPa, greater than or equal to 120 MPa and less than or equal to 140 MPa, greater than or equal to 130 MPa and less than or equal to 140 MPa, greater than or equal to 100 MPa and less than or equal to 130 MPa, greater than or equal to 110 MPa and less than or equal to 130 MPa, greater than or equal to 120 MPa and less than or equal to 130 MPa, greater than or equal to 100 MPa and less than or equal to 120 MPa, greater than or equal to 110 MPa and less than or equal to 120 MPa, or greater than or equal to 100 MPa and less than or equal to 110 MPa. It should be understood that the above ranges include all subranges within the explicitly disclosed ranges.

In embodiments, the glass-ceramics have a ratio of CS to CT (CS/CT) that is greater than or equal to 1.5 and less than or equal to 3.0, such as greater than or equal to 1.8 and less than or equal to 3.0, greater than or equal to 2.0 and less than or equal to 3.0, greater than or equal to 2.2 and less than or equal to 3.0, greater than or equal to 2.5 and less than or equal to 3.0, greater than or equal to 2.8 and less than or equal to 3.0, greater than or equal to 1.5 and less than or equal to 2.8, such as greater than or equal to 1.8 and less than or equal to 2.8, greater than or equal to 2.0 and less than or equal to 2.8, greater than or equal to 2.2 and less than or equal to 2.8, greater than or equal to 2.5 and less than or equal to 2.8, greater than or equal to 1.5 and less than or equal to 2.5, such as greater than or equal to 1.8 and less than or equal to 2.5, greater than or equal to 2.0 and less than or equal to 2.5, greater than or equal to 2.2 and less than or equal to 2.5, greater than or equal to 1.5 and less than or equal to 2.2, such as greater than or equal to 1.8 and less than or equal to 2.2, greater than or equal to 2.0 and less than or equal to 2.2, greater than or equal to 1.5 and less than or equal to 2.0, such as greater than or equal to 1.8 and less than or equal to 2.0, or greater than or equal to 1.5 and less than or equal to 1.8. It should be understood that the above ranges include all subranges within the explicitly disclosed ranges.

Glass-ceramic articles according to embodiments have a stress that decreases with increasing distance from the surface of the glass article toward the centerline of the glass article, and the stress decreases as a substantially linear function from a depth that is greater than or equal to 0.07 t and less than or equal to 0.26 t, greater than or equal to 0.10 t and less than or equal to 0.26 t, greater than or equal to 0.12 t and less than or equal to 0.26 t, greater than or equal to 0.15 t and less than or equal to 0.26 t, greater than or equal to 0.17 t and less than or equal to 0.26 t, greater than or equal to 0.20 t and less than or equal to 0.26 t, greater than or equal to 0.22 t and less than or equal to 0.26 t, greater than or equal to 0.25 t and less than or equal to 0.26 t, greater than or equal to 0.07 t and less than or equal to 0.25 t, greater than or equal to 0.10 t and less than or equal to 0.25 t, greater than or equal to 0.12 t and less than or equal to 0.25 t, greater than or equal to 0.15 t and less than or equal to 0.25 t, greater than or equal to 0.17 t and less than or equal to 0.25 t, greater than or equal to 0.20 t and less than or equal to 0.25 t, greater than or equal to 0.22 t and less than or equal to 0.25 t, greater than or equal to 0.07 t and less than or equal to 0.22 t, greater than or equal to 0.10 t and less than or equal to 0.22 t, greater than or equal to 0.12 t and less than or equal to 0.22 t, greater than or equal to 0.15 t and less than or equal to 0.22 t, greater than or equal to 0.17 t and less than or equal to 0.22 t, greater than or equal to 0.20 t and less than or equal to 0.22 t, greater than or equal to 0.07 t and less than or equal to 0.20 t, greater than or equal to 0.10 t and less than or equal to 0.20 t, greater than or equal to 0.12 t and less than or equal to 0.20 t, greater than or equal to 0.15 t and less than or equal to 0.20 t, greater than or equal to 0.17 t and less than or equal to 0.20 t, greater than or equal to 0.07 t and less than or equal to 0.17 t, greater than or equal to 0.10 t and less than or equal to 0.17 t, greater than or equal to 0.12 t and less than or equal to 0.17 t, greater than or equal to 0.15 t and less than or equal to 0.17 t, greater than or equal to 0.07 t and less than or equal to 0.15 t, greater than or equal to 0.10 t and less than or equal to 0.15 t, greater than or equal to 0.12 t and less than or equal to 0.15 t, greater than or equal to 0.07 t and less than or equal to 0.12 t, greater than or equal to 0.10 t and less than or equal to 0.12 t, or greater than or equal to 0.07 t and less than or equal to 0.10 t. It should be understood that the above ranges include all subranges within the explicitly disclosed ranges.

According to embodiments, the stress in the glass-ceramic article transitions from compressive stress to tensile stress at a depth measured from a surface of the class-ceramic article toward the centerline of the glass-ceramic article that is greater than or equal to 0.18 t and less than or equal to 0.25 t, greater than or equal to 0.19 t and less than or equal to 0.25 t, greater than or equal to 0.20 t and less than or equal to 0.25 t, greater than or equal to 0.21 t and less than or equal to 0.25 t, greater than or equal to 0.22 t and less than or equal to 0.25 t, greater than or equal to 0.23 t and less than or equal to 0.25 t, greater than or equal to 0.24 t and less than or equal to 0.25 t, greater than or equal to 0.18 t and less than or equal to 0.24 t, greater than or equal to 0.19 t and less than or equal to 0.24 t, greater than or equal to 0.20 t and less than or equal to 0.24 t, greater than or equal to 0.21 t and less than or equal to 0.24 t, greater than or equal to 0.22 t and less than or equal to 0.24 t, greater than or equal to 0.23 t and less than or equal to 0.24 t, greater than or equal to 0.18 t and less than or equal to 0.23 t, greater than or equal to 0.19 t and less than or equal to 0.23 t, greater than or equal to 0.20 t and less than or equal to 0.23 t, greater than or equal to 0.21 t and less than or equal to 0.23 t, greater than or equal to 0.22 t and less than or equal to 0.23 t, greater than or equal to 0.18 t and less than or equal to 0.22 t, greater than or equal to 0.19 t and less than or equal to 0.22 t, greater than or equal to 0.20 t and less than or equal to 0.22 t, greater than or equal to 0.21 t and less than or equal to 0.22 t, greater than or equal to 0.18 t and less than or equal to 0.21 t, greater than or equal to 0.19 t and less than or equal to 0.21 t, greater than or equal to 0.20 t and less than or equal to 0.21 t, greater than or equal to 0.18 t and less than or equal to 0.20 t, greater than or equal to 0.19 t and less than or equal to 0.20 t, or greater than or equal to 0.18 t and less than or equal to 0.19 t. It should be understood that the above ranges include all subranges within the explicitly disclosed ranges.

According to embodiments, the glass-ceramic article has a maximum central tension (mCT) and the absolute value of the surface compressive stress measured at a surface of the glass-ceramic article is greater than or equal to 1.5 mCT and less than or equal to 2.5 mCT, greater than or equal to 1.7 mCT and less than or equal to 2.5 mCT, greater than or equal to 2.0 mCT and less than or equal to 2.5 mCT, greater than or equal to 2.2 mCT and less than or equal to 2.5 mCT, greater than or equal to 1.5 mCT and less than or equal to 2.2 mCT, greater than or equal to 1.7 mCT and less than or equal to 2.2 mCT, greater than or equal to 2.0 mCT and less than or equal to 2.2 mCT, greater than or equal to 1.5 mCT and less than or equal to 2.0 mCT, greater than or equal to 1.7 mCT and less than or equal to 2.0 mCT, or greater than or equal to 1.5 mCT and less than or equal to 1.7 mCT. It should be understood that the above ranges include all subranges within the explicitly disclosed ranges.

In embodiments, the stored strain energy of the glass-ceramic article is greater than or equal to 22 J/m² and less than or equal to 60 J/m², such as greater than or equal to 25 J/m² and less than or equal to 60 J/m², greater than or equal to 30 J/m² and less than or equal to 60 J/m², greater than or equal to 35 J/m² and less than or equal to 60 J/m², greater than or equal to 40 J/m² and less than or equal to 60 J/m², greater than or equal to 45 J/m² and less than or equal to 60 J/m², greater than or equal to 50 J/m² and less than or equal to 60 J/m², greater than or equal to 55 J/m² and less than or equal to 60 J/m², greater than or equal to 22 J/m² and less than or equal to 55 J/m², such as greater than or equal to 25 J/m² and less than or equal to 55 J/m², greater than or equal to 30 J/m² and less than or equal to 55 J/m², greater than or equal to 35 J/m² and less than or equal to 55 J/m², greater than or equal to 40 J/m² and less than or equal to 55 J/m², greater than or equal to 45 J/m² and less than or equal to 55 J/m², greater than or equal to 50 J/m² and less than or equal to 55 J/m², greater than or equal to 22 J/m² and less than or equal to 50 J/m², such as greater than or equal to 25 J/m² and less than or equal to 50 J/m², greater than or equal to 30 J/m² and less than or equal to 50 J/m², greater than or equal to 35 J/m² and less than or equal to 50 J/m², greater than or equal to 40 J/m² and less than or equal to 50 J/m², greater than or equal to 45 J/m² and less than or equal to 50 J/m², greater than or equal to 22 J/m² and less than or equal to 45 J/m², such as greater than or equal to 25 J/m² and less than or equal to 45 J/m², greater than or equal to 30 J/m² and less than or equal to 45 J/m², greater than or equal to 35 J/m² and less than or equal to 45 J/m², greater than or equal to 40 J/m² and less than or equal to 45 J/m², greater than or equal to 22 J/m² and less than or equal to 40 J/m², such as greater than or equal to 25 J/m² and less than or equal to 40 J/m², greater than or equal to 30 J/m² and less than or equal to 40 J/m², greater than or equal to 35 J/m² and less than or equal to 40 J/m², greater than or equal to 22 J/m² and less than or equal to 35 J/m², such as greater than or equal to 25 J/m² and less than or equal to 35 J/m², greater than or equal to 30 J/m² and less than or equal to 35 J/m², greater than or equal to 22 J/m² and less than or equal to 30 J/m², such as greater than or equal to 25 J/m² and less than or equal to 30 J/m², or greater than or equal to 22 J/m² and less than or equal to 25 J/m². It should be understood that the above ranges include all subranges within the explicitly disclosed ranges. The glass-ceramic achieves the aforementioned stored strain energy with no bifurcation in crack pattern.

In embodiments, the glass-ceramic article has a thickness t that is greater than or equal to 0.1 mm and less than or equal to 2.0 mm, greater than or equal to 0.3 mm and less than or equal to 2.0 mm, greater than or equal to 0.5 mm and less than or equal to 2.0 mm, greater than or equal to 0.8 mm and less than or equal to 2.0 mm, greater than or equal to 1.0 mm and less than or equal to 2.0 mm, greater than or equal to 1.3 mm and less than or equal to 2.0 mm, greater than or equal to 1.5 mm and less than or equal to 2.0 mm, greater than or equal to 1.8 mm and less than or equal to 2.0 mm, greater than or equal to 0.1 mm and less than or equal to 1.8 mm, greater than or equal to 0.3 mm and less than or equal to 1.8 mm, greater than or equal to 0.5 mm and less than or equal to 1.8 mm, greater than or equal to 0.8 mm and less than or equal to 1.8 mm, greater than or equal to 1.0 mm and less than or equal to 1.8 mm, greater than or equal to 1.3 mm and less than or equal to 1.8 mm, greater than or equal to 1.5 mm and less than or equal to 1.8 mm, greater than or equal to 0.1 mm and less than or equal to 1.5 mm, greater than or equal to 0.3 mm and less than or equal to 1.5 mm, greater than or equal to 0.5 mm and less than or equal to 1.5 mm, greater than or equal to 0.8 mm and less than or equal to 1.5 mm, greater than or equal to 1.0 mm and less than or equal to 1.5 mm, greater than or equal to 1.3 mm and less than or equal to 1.5 mm, greater than or equal to 0.1 mm and less than or equal to 1.3 mm, greater than or equal to 0.3 mm and less than or equal to 1.3 mm, greater than or equal to 0.5 mm and less than or equal to 1.3 mm, greater than or equal to 0.8 mm and less than or equal to 1.3 mm, greater than or equal to 1.0 mm and less than or equal to 1.3 mm, greater than or equal to 0.1 mm and less than or equal to 1.0 mm, greater than or equal to 0.3 mm and less than or equal to 1.0 mm, greater than or equal to 0.5 mm and less than or equal to 1.0 mm, greater than or equal to 0.8 mm and less than or equal to 1.0 mm, greater than or equal to 0.1 mm and less than or equal to 0.8 mm, greater than or equal to 0.3 mm and less than or equal to 0.8 mm, greater than or equal to 0.5 mm and less than or equal to 0.8 mm, greater than or equal to 0.1 mm and less than or equal to 0.5 mm, greater than or equal to 0.3 mm and less than or equal to 0.5 mm, or greater than or equal to 0.1 mm and less than or equal to 0.3 mm. It should be understood that the above ranges include all subranges within the explicitly disclosed ranges.

In embodiments, the glass-ceramic article may be substantially planar and flat. In other embodiments, the glass-ceramic article may be shaped, for example it may have a 2.5D or 3D shape. In embodiments, the glass-ceramic article may have a uniform thickness and in other embodiments, the glass-ceramic article may not have a uniform thickness.

In embodiments, the fracture toughness of the glass-ceramic article is greater than or equal to 1.0 MPa√m and less than or equal to 2.0 MPa√m, greater than or equal to 1.2 MPa√m and less than or equal to 2.0 MPa√m, greater than or equal to 1.4 MPa√m and less than or equal to 2.0 MPa√m, greater than or equal to 1.5 MPa√m and less than or equal to 2.0 MPa√m, greater than or equal to 1.6 MPa√m and less than or equal to 2.0 MPa√m, greater than or equal to 1.8 MPa√m and less than or equal to 2.0 MPa√m, greater than or equal to 1.0 MPa√m and less than or equal to 1.8 MPa√m, greater than or equal to 1.2 MPa√m and less than or equal to 1.8 MPa√m, greater than or equal to 1.4 MPa√m and less than or equal to 1.8 MPa√m, greater than or equal to 1.5 MPa√m and less than or equal to 1.8 MPa√m, greater than or equal to 1.6 MPa√m and less than or equal to 1.8 MPa√m, greater than or equal to 1.0 MPa√m and less than or equal to 1.6 MPa√m, greater than or equal to 1.2 MPa√m and less than or equal to 1.6 MPa√m, greater than or equal to 1.4 MPa√m and less than or equal to 1.6 MPa√m, greater than or equal to 1.5 MPa√m and less than or equal to 1.6 MPa√m, greater than or equal to 1.0 MPa√m and less than or equal to 1.5 MPa√m, greater than or equal to 1.2 MPa√m and less than or equal to 1.5 MPa√m, greater than or equal to 1.4 MPa√m and less than or equal to 1.5 MPa√m, greater than or equal to 1.0 MPa√m and less than or equal to 1.4 MPa√m, greater than or equal to 1.2 MPa√m and less than or equal to 1.4 MPa√m, or greater than or equal to 1.0 MPa√m and less than or equal to 1.2 MPa√m. It should be understood that the above ranges include all subranges within the explicitly disclosed ranges.

In embodiments, the Youngs modulus (also referred to as elastic modulus) of the non-chemically strengthened glass-ceramic article is greater than or equal to 90 GPa and less than or equal to 200 GPa, such as greater than or equal to 100 GPa and less than or equal to 200 GPa, greater than or equal to 120 GPa and less than or equal to 200 GPa, greater than or equal to 140 GPa and less than or equal to 200 GPa, greater than or equal to 160 GPa and less than or equal to 200 GPa, greater than or equal to 180 GPa and less than or equal to 200 GPa, greater than or equal to 90 GPa and less than or equal to 180 GPa, such as greater than or equal to 100 GPa and less than or equal to 180 GPa, greater than or equal to 120 GPa and less than or equal to 180 GPa, greater than or equal to 140 GPa and less than or equal to 180 GPa, greater than or equal to 160 GPa and less than or equal to 180 GPa, greater than or equal to 90 GPa and less than or equal to 160 GPa, such as greater than or equal to 100 GPa and less than or equal to 160 GPa, greater than or equal to 120 GPa and less than or equal to 160 GPa, greater than or equal to 140 GPa and less than or equal to 160 GPa, greater than or equal to 90 GPa and less than or equal to 140 GPa, such as greater than or equal to 100 GPa and less than or equal to 140 GPa, greater than or equal to 120 GPa and less than or equal to 140 GPa, greater than or equal to 90 GPa and less than or equal to 120 GPa, such as greater than or equal to 100 GPa and less than or equal to 120 GPa, or greater than or equal to 90 GPa and less than or equal to 100 GPa. It should be understood that the above ranges include all subranges within the explicitly disclosed ranges.

In embodiments, the non-chemically strengthened glass-ceramic articles have a Poisson's ratio that is greater than or equal to 0.15 and less than or equal to 0.25, greater than or equal to 0.17 and less than or equal to 0.25, greater than or equal to 0.20 and less than or equal to 0.25, greater than or equal to 0.22 and less than or equal to 0.25, greater than or equal to 0.15 and less than or equal to 0.22, greater than or equal to 0.17 and less than or equal to 0.22, greater than or equal to 0.20 and less than or equal to 0.22, greater than or equal to 0.15 and less than or equal to 0.20, greater than or equal to 0.17 and less than or equal to 0.20, or greater than or equal to 0.15 and less than or equal to 0.17. It should be understood that the above ranges include all subranges within the explicitly disclosed ranges.

In embodiments, the non-chemically strengthened glass-ceramic articles have a shear modulus that is greater than or equal to 40 GPa and less than or equal to 50 GPa, greater than or equal to 43 GPa and less than or equal to 50 GPa, greater than or equal to 45 GPa and less than or equal to 50 GPa, greater than or equal to 48 GPa and less than or equal to 50 GPa, greater than or equal to 40 GPa and less than or equal to 48 GPa, greater than or equal to 43 GPa and less than or equal to 48 GPa, greater than or equal to 45 GPa and less than or equal to 48 GPa, greater than or equal to 40 GPa and less than or equal to 45 GPa, greater than or equal to 43 GPa and less than or equal to 45 GPa, or greater than or equal to 40 GPa and less than or equal to 43 GPa. It should be understood that the above ranges include all subranges within the explicitly disclosed ranges.

The fracture stress was measured by applied fracture stress to failure with a 4 point bending test after introducing about 80 m deep flaws using sand paper impact via an 1000 grit, 180 grit, and 80 grit slapper. Testing was performed using an apparatus comprising a simple pendulum-based dynamic impact test having a surface ranging from flat to curved, where the glass-ceramic article test specimen is mounted to a bob of a pendulum, which is then used to cause the test specimen to contact a roughened impact surface. The apparatus is described in detail in International Application Publication No. WO2017/100646, which is hereby incorporated by reference in its entirety. To perform the test, the sample is loaded on the holder and then pulled backwards from the pendulum equilibrium position and released to make a dynamic impact on the impact surface.

The fracture stress of the glass-ceramic according to embodiments measured on a glass-ceramic article having a thickness of 0.6 mm using 1000 grit is greater than or equal to 450 MPa and less than or equal to 550 MPa, greater than or equal to 475 MPa and less than or equal to 550 MPa, greater than or equal to 500 MPa and less than or equal to 550 MPa, greater than or equal to 525 MPa and less than or equal to 550 MPa, greater than or equal to 450 MPa and less than or equal to 525 MPa, greater than or equal to 475 MPa and less than or equal to 525 MPa, greater than or equal to 500 MPa and less than or equal to 525 MPa, greater than or equal to 450 MPa and less than or equal to 500 MPa, greater than or equal to 475 MPa and less than or equal to 500 MPa, or greater than or equal to 450 MPa and less than or equal to 475 MPa. It should be understood that the above ranges include all subranges within the explicitly disclosed ranges.

The fracture strength of the glass-ceramic according to embodiments measured on a glass-ceramic article having a thickness of 0.5 mm using 1000 grit is greater than or equal to 475 MPa and less than or equal to 550 MPa, greater than or equal to 500 MPa and less than or equal to 550 MPa, greater than or equal to 525 MPa and less than or equal to 550 MPa, greater than or equal to 475 MPa and less than or equal to 525 MPa, greater than or equal to 500 MPa and less than or equal to 525 MPa, or greater than or equal to 475 MPa and less than or equal to 500 MPa, It should be understood that the above ranges include all subranges within the explicitly disclosed ranges.

The fracture strength of the glass-ceramic according to embodiments measured on a glass-ceramic article having a thickness of 0.6 mm using 180 grit is greater than or equal to 400 MPa and less than or equal to 500 MPa, greater than or equal to 425 MPa and less than or equal to 500 MPa, greater than or equal to 450 MPa and less than or equal to 500 MPa, greater than or equal to 475 MPa and less than or equal to 500 MPa, greater than or equal to 400 MPa and less than or equal to 475 MPa, greater than or equal to 425 MPa and less than or equal to 475 MPa, greater than or equal to 450 MPa and less than or equal to 475 MPa, greater than or equal to 400 MPa and less than or equal to 450 MPa, greater than or equal to 425 MPa and less than or equal to 450 MPa, or greater than or equal to 400 MPa and less than or equal to 425 MPa. It should be understood that the above ranges include all subranges within the explicitly disclosed ranges.

The fracture strength of the glass-ceramic according to embodiments measured on a glass-ceramic article having a thickness of 0.5 mm using 180 grit is greater than or equal to 350 MPa and less than or equal to 450 MPa, greater than or equal to 375 MPa and less than or equal to 450 MPa, greater than or equal to 400 MPa and less than or equal to 450 MPa, greater than or equal to 425 MPa and less than or equal to 450 MPa, greater than or equal to 350 MPa and less than or equal to 425 MPa, greater than or equal to 375 MPa and less than or equal to 425 MPa, greater than or equal to 400 MPa and less than or equal to 425 MPa, greater than or equal to 350 MPa and less than or equal to 400 MPa, greater than or equal to 375 MPa and less than or equal to 400 MPa, or greater than or equal to 350 MPa and less than or equal to 375 MPa. It should be understood that the above ranges include all subranges within the explicitly disclosed ranges.

The fracture strength of the glass-ceramic according to embodiments measured on a glass-ceramic article having a thickness of 0.6 mm using 80 grit is greater than or equal to 350 MPa and less than or equal to 450 MPa, greater than or equal to 375 MPa and less than or equal to 450 MPa, greater than or equal to 400 MPa and less than or equal to 450 MPa, greater than or equal to 425 MPa and less than or equal to 450 MPa, greater than or equal to 350 MPa and less than or equal to 425 MPa, greater than or equal to 375 MPa and less than or equal to 425 MPa, greater than or equal to 400 MPa and less than or equal to 425 MPa, greater than or equal to 350 MPa and less than or equal to 400 MPa, greater than or equal to 375 MPa and less than or equal to 400 MPa, or greater than or equal to 350 MPa and less than or equal to 375 MPa. It should be understood that the above ranges include all subranges within the explicitly disclosed ranges.

The fracture strength of the glass-ceramic according to embodiments measured on a glass-ceramic article having a thickness of 0.5 mm using 80 grit is greater than or equal to 300 MPa and less than or equal to 400 MPa, greater than or equal to 325 MPa and less than or equal to 400 MPa, greater than or equal to 350 MPa and less than or equal to 400 MPa, greater than or equal to 375 MPa and less than or equal to 400 MPa, greater than or equal to 300 MPa and less than or equal to 375 MPa, greater than or equal to 325 MPa and less than or equal to 375 MPa, greater than or equal to 350 MPa and less than or equal to 375 MPa, greater than or equal to 300 MPa and less than or equal to 350 MPa, greater than or equal to 325 MPa and less than or equal to 350 MPa, or greater than or equal to 300 MPa and less than or equal to 325 MPa. It should be understood that the above ranges include all subranges within the explicitly disclosed ranges.

The Drop Test Method is used to determine the drop strength of the glass or glass-ceramic. The Drop Test Method involves performing face-drop testing on a puck with a glass or glass ceramic article attached thereto. The glass or glass ceramic article to be tested has a thickness similar or equal to the thickness that will be used in a given hand-held consumer electronic device. A puck refers to a structure meant to mimic the size, shape, and weight distribution of a given device, such as a cell phone. Hereinafter, the term “puck,” refers to a structure that has a weight of 126.0 grams, a length of 133.1 mm, a width of 68.2 mm, and a height of 9.4 mm.

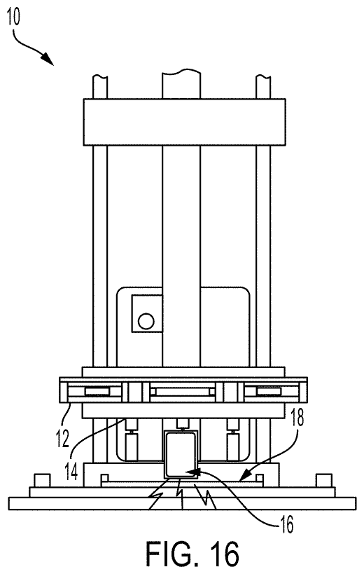

An exemplary device-drop machine that may be used to conduct the Drop Test Method is shown as reference number 10 in FIG. 14. The device-drop machine 10 includes a chuck 12 having chuck jaws 14. The puck 16 is staged in the chuck jaws 14 with the glass article attached thereto and facing downward. The chuck 12 is ready to fall from, for example, an electro-magnetic chuck lifter. Referring now to FIG. 15, the chuck 12 is released and during its fall, the chuck jaws 14 are triggered to open by, for example, a proximity sensor. As the chuck jaws 14 open, the puck 16 is released. Referring now to FIG. 16, the falling puck 16 strikes a drop surface 18. The drop surface 18 may be sandpaper, such as 180 grit sandpaper (however other grit sandpaper may be used as disclosed herein). If the glass or glass-ceramic article attached to the puck survives the fall (i.e., does not crack), the chuck 12 is set at an increased height and the test is repeated. The failure height is then the lowest height from which the puck including the glass or glass-ceramic article is dropped and the glass or glass-ceramic composition fails.

In embodiments the drop strength of a 0.6 mm thick glass-ceramic article is greater than or equal to 190 cm and less than or equal to 250 cm, greater than or equal to 200 cm and less than or equal to 250 cm, greater than or equal to 210 cm and less than or equal to 250 cm, greater than or equal to 220 cm and less than or equal to 250 cm, greater than or equal to 230 cm and less than or equal to 250 cm, greater than or equal to 240 cm and less than or equal to 250 cm, greater than or equal to 190 cm and less than or equal to 240 cm, greater than or equal to 200 cm and less than or equal to 240 cm, greater than or equal to 210 cm and less than or equal to 240 cm, greater than or equal to 220 cm and less than or equal to 240 cm, greater than or equal to 230 cm and less than or equal to 240 cm, greater than or equal to 190 cm and less than or equal to 230 cm, greater than or equal to 200 cm and less than or equal to 230 cm, greater than or equal to 210 cm and less than or equal to 230 cm, greater than or equal to 220 cm and less than or equal to 230 cm, greater than or equal to 190 cm and less than or equal to 220 cm, greater than or equal to 200 cm and less than or equal to 220 cm, greater than or equal to 210 cm and less than or equal to 220 cm, greater than or equal to 190 cm and less than or equal to 210 cm, greater than or equal to 200 cm and less than or equal to 210 cm, or greater than or equal to 190 cm and less than or equal to 200 cm. It should be understood that the above ranges include all subranges within the explicitly disclosed ranges.

In embodiments the drop strength of a 0.5 mm thick glass-ceramic article is greater than or equal to 180 cm and less than or equal to 240 cm, greater than or equal to 190 cm and less than or equal to 240 cm, greater than or equal to 200 cm and less than or equal to 240 cm, greater than or equal to 210 cm and less than or equal to 240 cm, greater than or equal to 220 cm and less than or equal to 240 cm, greater than or equal to 230 cm and less than or equal to 240 cm, greater than or equal to 180 cm and less than or equal to 230 cm, greater than or equal to 190 cm and less than or equal to 230 cm, greater than or equal to 200 cm and less than or equal to 230 cm, greater than or equal to 210 cm and less than or equal to 230 cm, greater than or equal to 220 cm and less than or equal to 230 cm, greater than or equal to 180 cm and less than or equal to 220 cm, greater than or equal to 190 cm and less than or equal to 220 cm, greater than or equal to 200 cm and less than or equal to 220 cm, greater than or equal to 210 cm and less than or equal to 220 cm, greater than or equal to 180 cm and less than or equal to 210 cm, greater than or equal to 190 cm and less than or equal to 210 cm, greater than or equal to 200 cm and less than or equal to 210 cm, greater than or equal to 180 cm and less than or equal to 200 cm, greater than or equal to 190 cm and less than or equal to 200 cm, or greater than or equal to 180 cm and less than or equal to 190 cm. It should be understood that the above ranges include all subranges within the explicitly disclosed ranges.

Non-strengthened glass-ceramics according to embodiments disclosed and described herein are also scratch resistant and have an onset load for lateral cracking that is greater than or equal to 0.50 Newtons (N) and less than or equal to 0.75 N, such as greater than or equal to 0.55 N and less than or equal to 0.75 N, greater than or equal to 0.60 N and less than or equal to 0.75 N, greater than or equal to 0.65 N and less than or equal to 0.75 N, greater than or equal to 0.70 N and less than or equal to 0.75 N, greater than or equal to 0.50 N and less than or equal to 0.70 N, greater than or equal to 0.55 N and less than or equal to 0.70 N, greater than or equal to 0.60 N and less than or equal to 0.70 N, greater than or equal to 0.65 N and less than or equal to 0.70 N, greater than or equal to 0.50 N and less than or equal to 0.65 N, greater than or equal to 0.55 N and less than or equal to 0.65 N, greater than or equal to 0.60 N and less than or equal to 0.65 N, greater than or equal to 0.50 N and less than or equal to 0.60 N, greater than or equal to 0.55 N and less than or equal to 0.60 N, or greater than or equal to 0.50 N and less than or equal to 0.55 N. It should be understood that the above ranges include all subranges within the explicitly disclosed ranges.

Glass-ceramics according to embodiments have a Vickers Hardness (at 200 g load) measured on an unstrengthened glass-ceramic that is greater than or equal to 740 Kg_{f}/mm² and less than or equal to 820 Kg_{f}/mm², such as greater than or equal to 760 Kg_{f}/mm² and less than or equal to 820 Kg_{f}/mm², greater than or equal to 780 Kg_{f}/mm² and less than or equal to 820 Kg_{f}/mm², greater than or equal to 800 Kg_{f}/mm² and less than or equal to 820 Kg_{f}/mm², greater than or equal to 740 Kg_{f}/mm² and less than or equal to 800 Kg_{f}/mm², such as greater than or equal to 760 Kg_{f}/mm² and less than or equal to 800 Kg_{f}/mm², greater than or equal to 780 Kg_{f}/mm² and less than or equal to 800 Kg_{f}/mm², greater than or equal to 740 Kg_{f}/mm² and less than or equal to 780 Kg_{f}/mm², such as greater than or equal to 760 Kg_{f}/mm² and less than or equal to 780 Kg_{f}/mm², or greater than or equal to 740 Kg_{f}/mm² and less than or equal to 760 Kg_{f}/mm². It should be understood that the above ranges include all subranges within the explicitly disclosed ranges.

Embodiments of glass-ceramics have an annealing point that is greater than or equal to 750° C. and less than or equal to 770° C., greater than or equal to 755° C. and less than or equal to 770° C., greater than or equal to 760° C. and less than or equal to 770° C., greater than or equal to 765° C. and less than or equal to 770° C., greater than or equal to 750° C. and less than or equal to 765° C., greater than or equal to 755° C. and less than or equal to 765° C., greater than or equal to 760° C. and less than or equal to 765° C., greater than or equal to 750° C. and less than or equal to 760° C., greater than or equal to 755° C. and less than or equal to 760° C., or greater than or equal to 750° C. and less than or equal to 755° C. It should be understood that the above ranges include all subranges within the explicitly disclosed ranges.

Glass-ceramics according to embodiments have a strain point that is greater than or equal to 700° C. and less than or equal to 750° C., greater than or equal to 710° C. and less than or equal to 750° C., greater than or equal to 720° C. and less than or equal to 750° C., greater than or equal to 725° C. and less than or equal to 750° C., greater than or equal to 730° C. and less than or equal to 750° C., greater than or equal to 740° C. and less than or equal to 750° C., greater than or equal to 700° C. and less than or equal to 740° C., greater than or equal to 710° C. and less than or equal to 740° C., greater than or equal to 720° C. and less than or equal to 740° C., greater than or equal to 725° C. and less than or equal to 740° C., greater than or equal to 730° C. and less than or equal to 740° C., greater than or equal to 700° C. and less than or equal to 730° C., greater than or equal to 710° C. and less than or equal to 730° C., greater than or equal to 720° C. and less than or equal to 730° C., greater than or equal to 725° C. and less than or equal to 730° C., greater than or equal to 700° C. and less than or equal to 725° C., greater than or equal to 710° C. and less than or equal to 725° C., greater than or equal to 720° C. and less than or equal to 725° C., greater than or equal to 700° C. and less than or equal to 720° C., greater than or equal to 710° C. and less than or equal to 720° C., or greater than or equal to 700° C. and less than or equal to 710° C. It should be understood that the above ranges include all subranges within the explicitly disclosed ranges.

According to embodiments, glass-ceramics have a refraction index (measured at wavelengths of 598 nm) that is greater than or equal to 1.500 and less than or equal to 1.600, greater than or equal to 1.520 and less than or equal to 1.600, greater than or equal to 1.540 and less than or equal to 1.600, greater than or equal to 1.550 and less than or equal to 1.600, greater than or equal to 1.560 and less than or equal to 1.600, greater than or equal to 1.580 and less than or equal to 1.600, greater than or equal to 1.500 and less than or equal to 1.580, greater than or equal to 1.520 and less than or equal to 1.580, greater than or equal to 1.540 and less than or equal to 1.580, greater than or equal to 1.550 and less than or equal to 1.580, greater than or equal to 1.560 and less than or equal to 1.580, greater than or equal to 1.500 and less than or equal to 1.560, greater than or equal to 1.520 and less than or equal to 1.560, greater than or equal to 1.540 and less than or equal to 1.560, greater than or equal to 1.550 and less than or equal to 1.560, greater than or equal to 1.500 and less than or equal to 1.550, greater than or equal to 1.520 and less than or equal to 1.550, greater than or equal to 1.540 and less than or equal to 1.550, greater than or equal to 1.500 and less than or equal to 1.540, greater than or equal to 1.520 and less than or equal to 1.540, or greater than or equal to 1.500 and less than or equal to 1.520. It should be understood that the above ranges include all subranges within the explicitly disclosed ranges.

The stress optical coefficient (measured at a wavelength of 546 nm) of glass-ceramics according to embodiments is greater than or equal to 25.5 nm/cm/MPa and less than or equal to 26.5 nm/cm/MPa, greater than or equal to 25.8 nm/cm/MPa and less than or equal to 26.5 nm/cm/MPa, greater than or equal to 26.0 nm/cm/MPa and less than or equal to 26.5 nm/cm/MPa, greater than or equal to 26.2 nm/cm/MPa and less than or equal to 26.5 nm/cm/MPa, greater than or equal to 26.4 nm/cm/MPa and less than or equal to 26.5 nm/cm/MPa, greater than or equal to 25.5 nm/cm/MPa and less than or equal to 26.4 nm/cm/MPa, greater than or equal to 25.8 nm/cm/MPa and less than or equal to 26.4 nm/cm/MPa, greater than or equal to 26.0 nm/cm/MPa and less than or equal to 26.4 nm/cm/MPa, greater than or equal to 26.2 nm/cm/MPa and less than or equal to 26.4 nm/cm/MPa, greater than or equal to 25.5 nm/cm/MPa and less than or equal to 26.2 nm/cm/MPa, greater than or equal to 25.8 nm/cm/MPa and less than or equal to 26.2 nm/cm/MPa, greater than or equal to 26.0 nm/cm/MPa and less than or equal to 26.2 nm/cm/MPa, greater than or equal to 25.5 nm/cm/MPa and less than or equal to 26.0 nm/cm/MPa, greater than or equal to 25.8 nm/cm/MPa and less than or equal to 26.0 nm/cm/MPa, or greater than or equal to 25.5 nm/cm/MPa and less than or equal to 25.8 nm/cm/MPa. It should be understood that the above ranges include all subranges within the explicitly disclosed ranges.

According to embodiments, the glass-ceramics have a density that is greater than or equal to 2.40 g/cm³ and less than or equal to 2.60 g/cm³, greater than or equal to 2.42 g/cm³ and less than or equal to 2.60 g/cm³, greater than or equal to 2.45 g/cm³ and less than or equal to 2.60 g/cm³, greater than or equal to 2.48 g/cm³ and less than or equal to 2.60 g/cm³, greater than or equal to 2.50 g/cm³ and less than or equal to 2.60 g/cm³, greater than or equal to 2.52 g/cm³ and less than or equal to 2.60 g/cm³, greater than or equal to 2.55 g/cm³ and less than or equal to 2.60 g/cm³, greater than or equal to 2.58 g/cm³ and less than or equal to 2.60 g/cm³, greater than or equal to 2.40 g/cm³ and less than or equal to 2.58 g/cm³, greater than or equal to 2.42 g/cm³ and less than or equal to 2.58 g/cm³, greater than or equal to 2.45 g/cm³ and less than or equal to 2.58 g/cm³, greater than or equal to 2.48 g/cm³ and less than or equal to 2.58 g/cm³, greater than or equal to 2.50 g/cm³ and less than or equal to 2.58 g/cm³, greater than or equal to 2.52 g/cm³ and less than or equal to 2.58 g/cm³, greater than or equal to 2.55 g/cm³ and less than or equal to 2.58 g/cm³, greater than or equal to 2.40 g/cm³ and less than or equal to 2.55 g/cm³, greater than or equal to 2.42 g/cm³ and less than or equal to 2.55 g/cm³, greater than or equal to 2.45 g/cm³ and less than or equal to 2.55 g/cm³, greater than or equal to 2.48 g/cm³ and less than or equal to 2.55 g/cm³, greater than or equal to 2.50 g/cm³ and less than or equal to 2.55 g/cm³, greater than or equal to 2.52 g/cm³ and less than or equal to 2.55 g/cm³, greater than or equal to 2.40 g/cm³ and less than or equal to 2.52 g/cm³, greater than or equal to 2.42 g/cm³ and less than or equal to 2.52 g/cm³, greater than or equal to 2.45 g/cm³ and less than or equal to 2.52 g/cm³, greater than or equal to 2.48 g/cm³ and less than or equal to 2.52 g/cm³, greater than or equal to 2.50 g/cm³ and less than or equal to 2.52 g/cm³, greater than or equal to 2.40 g/cm³ and less than or equal to 2.50 g/cm³, greater than or equal to 2.42 g/cm³ and less than or equal to 2.50 g/cm³, greater than or equal to 2.45 g/cm³ and less than or equal to 2.50 g/cm³, greater than or equal to 2.48 g/cm³ and less than or equal to 2.50 g/cm³, greater than or equal to 2.40 g/cm³ and less than or equal to 2.48 g/cm³, greater than or equal to 2.42 g/cm³ and less than or equal to 2.48 g/cm³, greater than or equal to 2.45 g/cm³ and less than or equal to 2.48 g/cm³, greater than or equal to 2.40 g/cm³ and less than or equal to 2.45 g/cm³, greater than or equal to 2.42 g/cm³ and less than or equal to 2.45 g/cm³, or greater than or equal to 2.40 g/cm³ and less than or equal to 2.42 g/cm³. It should be understood that the above ranges include all subranges within the explicitly disclosed ranges.

### End Products

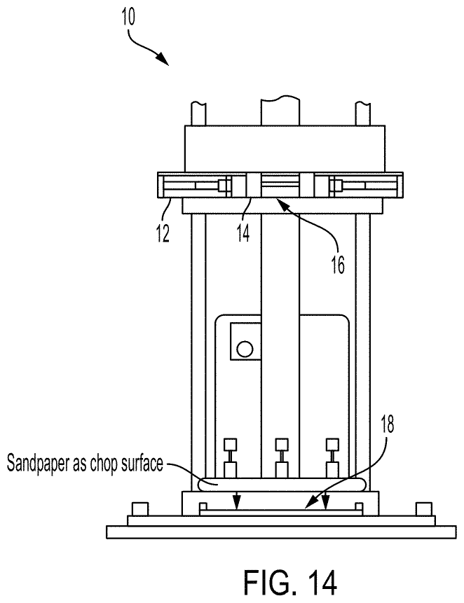

The glass and glass-ceramic articles disclosed herein may be incorporated into another article such as an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc. for example for use an interior display cover, a window, or windshield), appliance articles, or any article that requires some transparency, scratch-resistance, abrasion resistance or a combination thereof. An exemplary article incorporating any of the strengthened glass-ceramic articles disclosed herein is shown in FIGS. 12A and 12B.

Specifically, FIGS. 12A and 12B show a consumer electronic device 200 including a housing 202 having front 204, back 206, and side surfaces 208; electrical components (not shown) that are at least partially inside or entirely within the housing and including at least a controller, a memory, and a display 210 at or adjacent to the front surface of the housing; and a cover substrate 212 at or over the front surface of the housing such that it is over the display. In some embodiments, at least one of the cover substrate 212 or a portion of housing 202 may include any of the glass-ceramic strengthened articles disclosed herein.

Accordingly, various embodiments described herein may be employed to produce glass-ceramic articles having excellent optical quality and reduced warp while not adversely impacting, or even improving, stress in the glass-ceramic articles as compared to glass articles cerammed according to conventional techniques. Such glass-ceramic articles may be particularly well-suited for use in portable electronic devices due to their strength performance and high transmission values.

### EXAMPLES

Various embodiments will be further clarified by the following examples.

### Example 1

A glass precursor composition was formed by melting a composition show in Table 1 below, conventional glass melting processes were used:

TABLE 1
Composition (wt %)

| | |
|---|---|
| SiO₂ | 72.3 |
| Al₂O₃ | 7.2 |
| P₂O₅ | 2.5 |
| Li₂O | 11.6 |
| Na₂O | 0.07 |
| K₂O | 0.12 |
| ZrO₂ | 5.97 |
| Fe₂CO₃ | 0.06 |
| CaO | 0.7 |

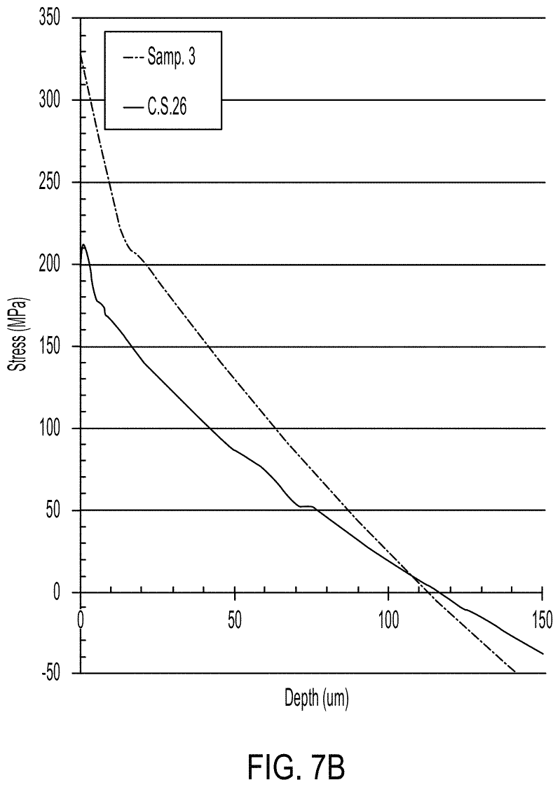

The glass precursor composition was formed into a glass article having a thickness of 0.6 mm and subjected to a heat treatment where the glass precursor was heating to a nucleation temperature of 575° C. and held for 3 hours, and then the glass precursor was heated to a growth temperature of 735° C. and held for 1 hour. FIG. 6 shows XRD spectrum for the glass-ceramic and shows primarily petalite and lithium disilicate crystalline phases with a small amount of virgilite. Comparative Samples were prepared in the same way from the following glass composition:

TABLE 2
Composition (wt %)

| | |
|---|---|
| SiO₂ | 74.5 |
| Al₂O₃ | 7.6 |
| P₂O₅ | 2.1 |
| Li₂O | 11.3 |
| Na₂O | 0.05 |
| K₂O | 0.12 |
| ZrO₂ | 4.31 |
| Fe₂O₃ | 0.06 |
| CaO | 0.03 |

### Example 2

Glass precursors were formed according Example 1 and subjected to a variety of 2-step heat treatments as shown in Table 2 below. The phase assemblages were measured by XRD for each sample and comparative sample, and the haze was also measured on 0.6 mm thick polished glass-ceramic articles using a BYK Hazegard I Pro setup. The results are shown in Table 3 below.

TABLE 3

| | | | | | Phase assemblage measured by XRD (in wt %) | | | | | | |
|---|---|---|---|---|---|---|---|---|---|---|---|
| | Nucleation | Nucleation. | Growth | Growth | Residual | | | Lithium | | | |
| | temperature | time | temperature | time | Glassy | Lithium | | Meta- | | | |
| Cycle ID | (° C.) | (hours) | (° C.) | (hours) | phase | Disilicate | Petalite | silicate | Virgilite | Cristobalite | Haze |
| Samp. 1 | 575 | 3 | 735 | 1 | 13 | 45 | 43 | 0 | 0.2 | 0 | 0.116 |
| C.S. 1 | 580 | 4 | 740 | 1 | 12 | 45 | 42 | 0 | 0.2 | 0 | 0.134 |
| C.S. 2 | 585 | 3 | 735 | 1 | 14 | 44 | 42 | 0 | 0.2 | 0 | 0.130 |
| C.S. 3 | 590 | 2.5 | 735 | 0.75 | 13 | 45 | 41 | trace | 0.4 | 0 | 0.126 |
| C.S. 4 | 585 | 3 | 735 | 1 | 13 | 46 | 41 | 0 | 0.2 | 0 | |
| C.S. 5 | 585 | 2.75 | 735 | 0.75 | 12 | 43 | 43 | 1.8 | 0.1 | 0 | 0.127 |
| C.S. 6 | 585 | 2.75 | 740 | 0.75 | 13 | 45 | 41 | 0 | 0.4 | 0 | |
| C.S. 7 | 585 | 3 | 735 | 1 | 13 | 45 | 42 | 0 | 0.2 | 0 | |
| C.S. 8 | 585 | 2.75 | 745 | 0.75 | 11 | 46 | 42 | 0 | 0.5 | 0 | 0.139 |
| C.S. 9 | 580 | 2.5 | 740 | 1 | 12 | 46 | 42 | 0 | 0.5 | 0 | 0.151 |
| C.S. 10 | 585 | 2.5 | 745 | 0.75 | 12 | 45 | 42 | 0 | 0.6 | 0 | 0.131 |
| C.S. 11 | 580 | 2.75 | 735 | 0.75 | 11 | 44 | 42 | 2.1 | 0.3 | 0 | |
| C.S. 12 | 580 | 2.75 | 735 | 0.75 | 12 | 44 | 42 | 2.3 | 0.3 | 0 | |
| Samp. 2 | 575 | 3 | 735 | 1 | 14 | 44 | 42 | trace | 0.3 | 0 | 0.118 |
| C.S. 13 | 590 | 2.75 | 725 | 0.75 | 13 | 40 | 45 | 2.59 | 0.2 | 0 | |
| C.S. 14 | 600 | 2.75 | 725 | 0.75 | 14 | 39 | 44 | 3.32 | 0.3 | 0 | |
| C.S. 15 | 600 | 2.75 | 735 | 0.75 | 13 | 44 | 42 | trace | 0.7 | 0 | 0.133 |
| C.S. 16 | 575 | 3 | 745 | 0.5 | 12 | 44 | 43 | 0 | 0.7 | 0 | 0.137 |
| C.S. 17 | 575 | 3 | 755 | 0.5 | 13 | 45 | 41 | 0 | 1.4 | 0 | 0.150 |
| C.S. 18 | 575 | 2.75 | 745 | 0.5 | 13 | 46 | 41 | 0 | 0.9 | 0 | 0.144 |
| C.S. 19 | 585 | 2.75 | 745 | 0.5 | 12 | 45 | 42 | 0 | 0.5 | 0 | 0.117 |
| C.S. 20 | 595 | 2.75 | 745 | 0.5 | 13 | 46 | 40 | 0 | 0.7 | 0 | |

### Example 3

A Glass precursor was formed according Example 1 and subjected to the 3-step heat treatments shown in Table 4. The phase assemblages were measured by XRD for the sample and comparative sample.

TABLE 4

| | | Intermediate | | | | Phase assemblage measured by XRD (in wt %) | | | | | |
|---|---|---|---|---|---|---|---|---|---|---|---|
| Nucleation | Nucleation | step | Intermediate | Growth | Growth | Residual | | | | | |
| temperature | time | temperature | step time | temperature | time | Glassy | Lithium | | Lithium | | |
| (° C.) | (hours) | (° C.) | (hours) | (° C.) | (hours) | phase | Disilicate | Petalite | Metasilicate | Virgilite | Cristobalite |
| 585 | 2.5 | 680 | 0.25 | 735 | 0.5 | 12 | 42 | 44 | 1.6 | 0.3 | 0 |

### Example 4

Glass precursors were formed according to Example 1 and subjected to the 2-step heat treatments shown in Table 5. The phase assemblages were measured by XRD for these comparative samples. None of the comparative samples in Table 4 have the desired phase assemblage.

TABLE 5

| | | | | | Phase assemblage measured by XRD (in wt %) | | | | | |
|---|---|---|---|---|---|---|---|---|---|---|
| | Nucleation | Nucleation | Growth | Growth | Residual | | | | | |
| | temperature | time | temperature | time | Glassy | Lithium | | Lithium | | |
| Cycle ID | (° C.) | (hours) | (° C.) | (hours) | phase | Disilicate | Petalite | Metasilicate | Virgilite | Cristobalite |
| C.S. 21 | 590 | 2.75 | 725 | 0.75 | 13 | 40 | 45 | 2.59 | 0.2 | 0 |
| C.S. 22 | 600 | 2.75 | 725 | 0.75 | 14 | 39 | 44 | 3.32 | 0.3 | 0 |
| C.S. 23 | 575 | 3 | 735 | 0.08 | 16 | 34 | 44 | 6.2 | 0.2 | |
| | | | | (5 min) | | | | | | |
| C.S. 24 | 600 | 2 h 45 | 755 | 0.75 | 14 | 43 | 41 | 0.0 | 1.9 | |
| C.S. 25 | 565 | 2 h 45 | 725 | 0.75 | 17 | 29 | 45 | 8.0 | 0.6 | |

### Example 5

Glass-ceramics prepared according to Samp. 1 in Example 2, but having 0.5 mm and 0.6 mm thicknesses, were subjected to chemical strengthening using the ion exchange conditions provide in Table 6 below. The compressive stress (CS), depth of compression (DOC), central tension (CT), ratio of CS/CT, and DOC normalized to thickness (i.e., DOC (mm)/thickness (mm)) are provided in Table 5. Comparative Examples 26 and 27 were cerammed at 580° C. for 2 hours and 45 minutes and then at 755° C. for 45 minutes.

TABLE 6

| | | IOX | | | | | DOC |
|---|---|---|---|---|---|---|---|
| | Thickness | (wt %, ° C., | CS | DOC | CT | | norm. to |
| Sample | (mm) | hours) | (MPa) | (μm) | (MPa) | CS/CT | thick |
| C.S. 26 | 0.6 | 60K/40Na/0.12Li, | 286 | 134 | 107 | 2.7 | 0.22 |
| | | 500° C., 6 hr | | | | | |
| Samp. 2 | 0.6 | 60K/40Na/0.12Li, | 312 | 137 | 150 | 2.1 | 0.23 |
| | | 500° C., 12 hr | | | | | |
| C.S. 27 | 0.5 | 60K/40Na/0.12Li, | 284 | 115 | 104 | 2.7 | 0.23 |
| | | 500° C., 5 hr | | | | | |
| Samp. 3 | 0.5 | 60K/40Na/0.12Li, | 324 | 118 | 150 | 2.2 | 0.24 |
| | | 500° C., 8 hr | | | | | |

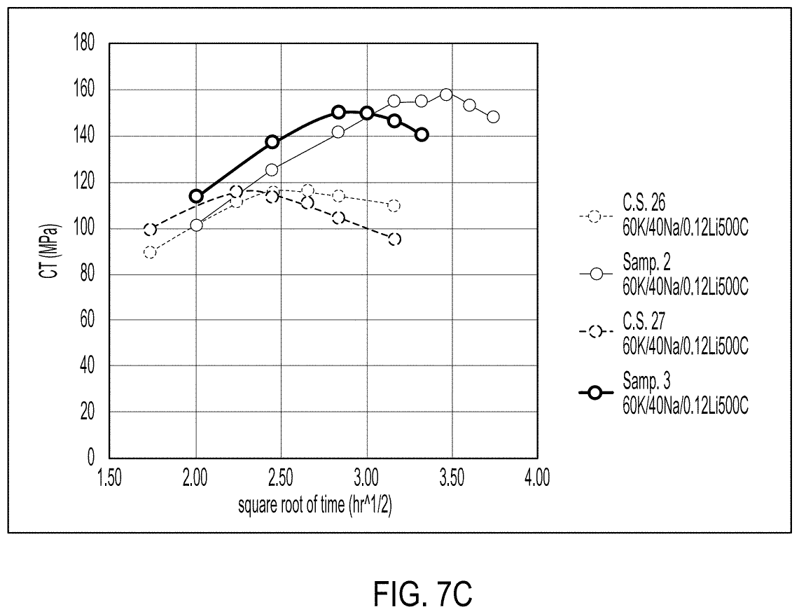

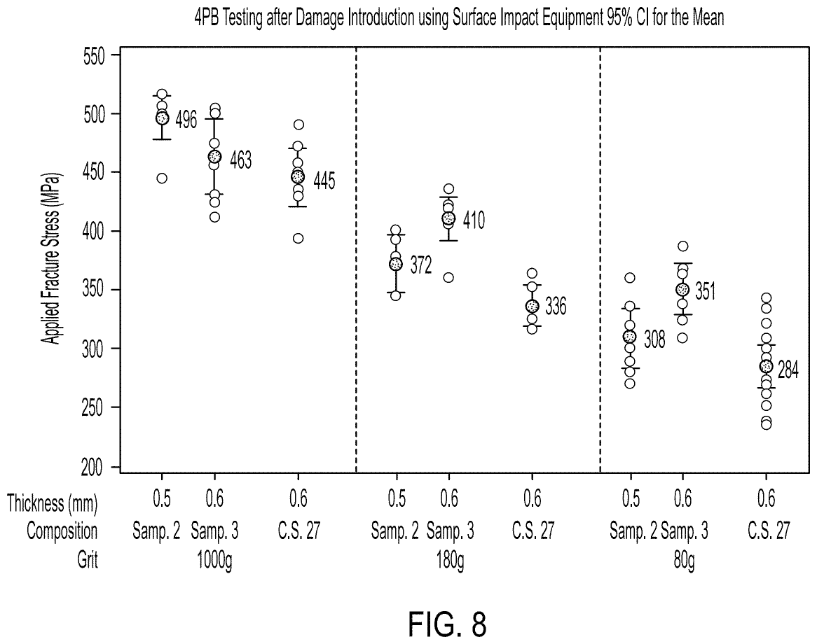

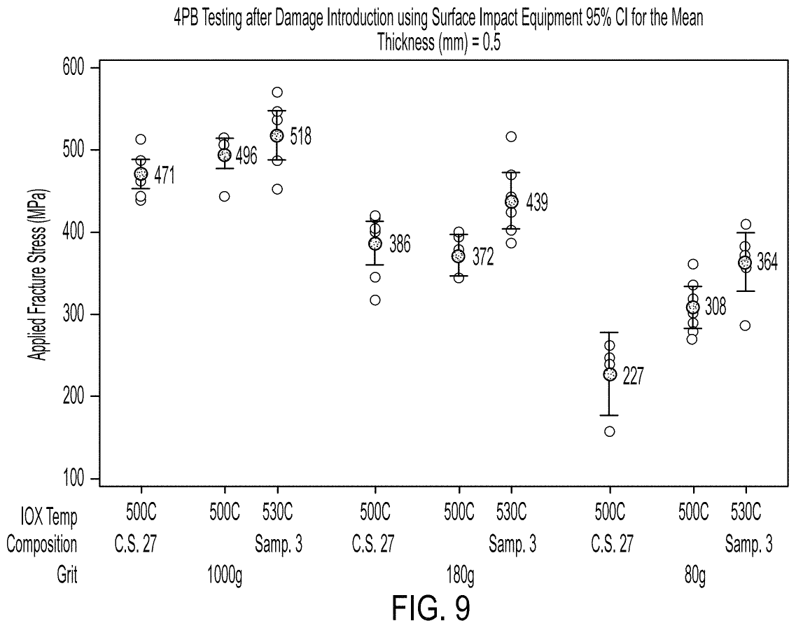

FIG. 7A shows the stress profiles of the glass-ceramics of C.S. 26 and Samp. 2, and FIG. 7B shows the stress profiles of the glass-ceramics of C.S. 27 and Samp. 3. Table 7 shows the data obtained in FIG. 7A and FIG. 7B.

TABLE 7

| | | CS Min | CS Max | DOC Min | DOC Max | CT Min | CT Max |
|---|---|---|---|---|---|---|---|
| Composition | Thickness | (MPa) | (MPa) | (μm) | (μm) | (MPa) | (MPa) |
| C.S. 26 | 0.6 mm | 200 | 350 | 120 | 150 | 90 | 125 |
| Samp. 2 | 0.6 mm | 225 | 375 | 120 | 155 | 135 | 170 |
| C.S. 27 | 0.5 mm | 200 | 350 | 65 | 125 | 90 | 125 |
| Samp. 3 | 0.5 mm | 225 | 375 | 100 | 135 | 135 | 170 |

FIG. 7C graphically depicts the central tension of glass-ceramics measured as a function (square root) of the duration of the ion exchange treatment. As shown in FIG. 7C, the central tension increases with duration of the ion exchange process to a point, and then the central tension begins to decrease; showing that tuning the duration of an ion exchange process maximizes central tension while just running the ion exchange for longer will not necessarily achieve maximum central tension.

### Example 6

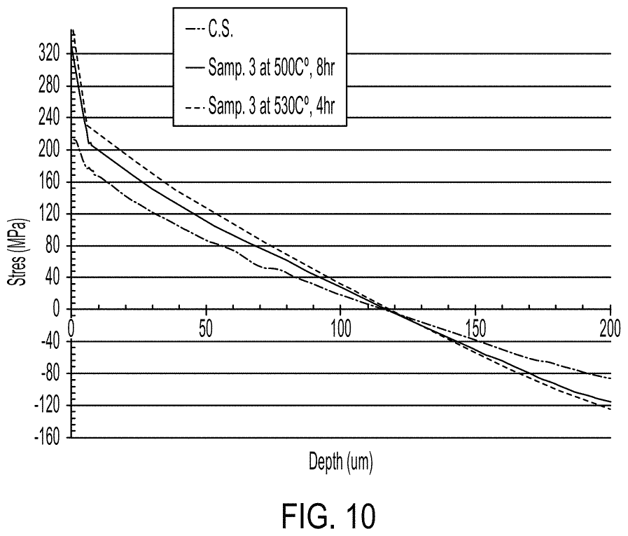

Damage resistance of Samp. 2, C.S. 26, Samp. 3, and C.S. 27 were conducted using surface impact equipment performed using an apparatus comprising a simple pendulum-based dynamic impact test having a surface ranging from flat to curved, where the glass-ceramic article test specimen is mounted to a bob of a pendulum, which is then used to cause the test specimen to contact a roughened impact surface. The apparatus is described in detail in International Application Publication No. WO2017/100646, which is hereby incorporated by reference in its entirety. To perform the test, the sample is loaded on the holder and then pulled backwards from the pendulum equilibrium position and released to make a dynamic impact on the impact surface. The results are shown in FIG. 8.

### Example 7

Stress profiles were measured using glass-ceramics of Samp. 3 and C.S. 27 were measured using the differing ion exchange conditions shown in Table 8.

TABLE 8

| | Thickness | | CS | CT | DOC |
|---|---|---|---|---|---|
| Sample | (mm) | IOX Conditions | (MPa) | (MPa) | (μm) |
| Samp. 3 | 0.5 | 60K/40Na + | 320 | 138 | 124 |
| | | 0.14Li 530 C. 4 h | | | |
| Samp. 3 | 0.5 | 60K/40Na + | 300 | 146 | 114 |
| | | 0.12Li 500 C. 8 h | | | |
| C.S. 27 | 0.5 | 60K/40Na + | 277 | 111 | 115 |
| | | 0.12Li 500 C. 5 h | | | |

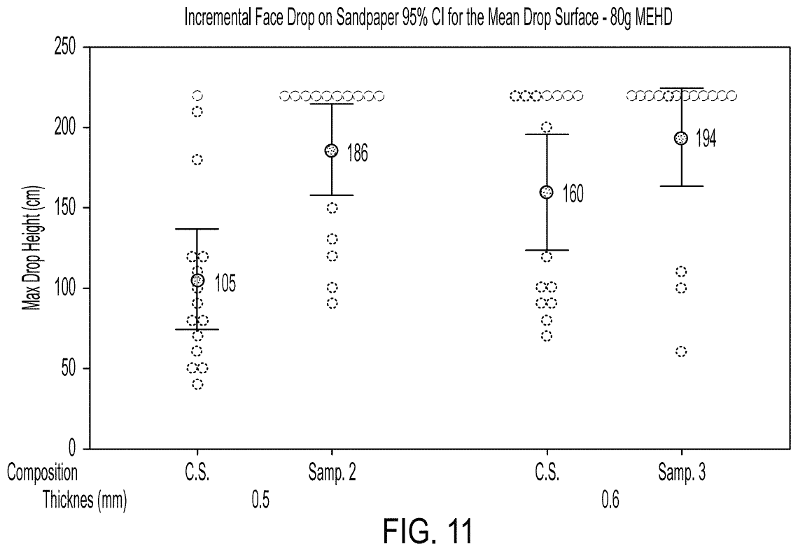

Damage resistance of these samples were conducted using surface impact equipment as described in Example 6. The results are shown in FIG. 9.

### Example 8

The effects of ion exchange temperature and duration were tested on glass-ceramics of Samp. 2 and Samp. 3 while maintaining an identical ion exchange medium of 60 wt % KNO₃, 40 wt % NaNO₃ and superadditions of 0.12 wt % LiNO₃, 0.5 wt % NaNO₂, and 0.5 wt % silicic acid. The ion exchange temperature and duration as well as compressive stress, central tension, and depth of compression are shown in Table 9 below.

TABLE 9

| | Temp. | Time | CS | CT | DOC |
|---|---|---|---|---|---|
| Sample No. | (° C.) | (hours) | (MPa) | (MPa) | (μm) |
| Samp. 2 | 500 | 12 | 345 | 158 | 137 |
| Samp. 2 | 530 | 6 | 348 | 166 | 138 |
| Samp. 3 | 500 | 8 | 330 | 152 | 118 |
| Samp. 3 | 530 | 4 | 363 | 159 | 115 |

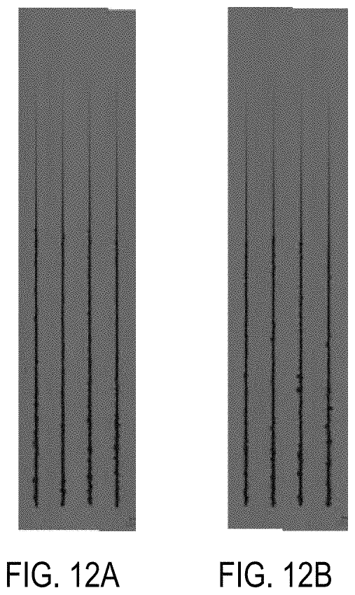

The stress profiles of Samp. 3 strengthened at 500° C. for 8 hours and strengthened at 530° C. for 4 hours as well as are shown in FIG. 10. The ion exchange conditions for the comparative sample are as follows: the bath consisted of 60 wt % KNO₃, 40 wt % NaNO₃, and 0.12 wt % LiNO₃ and was treated at 500° C. for 8 hours. Sample 3 was treated at bath consisted of 60 wt % KNO₃, 40 wt % NaNO₃, and 0.12 wt % LiNO₃ and was treated at 500° C. for 8 hours. Sample 3 was also treated at bath consisted of 60 wt % KNO₃, 40 wt % NaNO₃, and 0.12 wt % LiNO₃ and was treated at 530° C. for 4 hours.

### Example 9

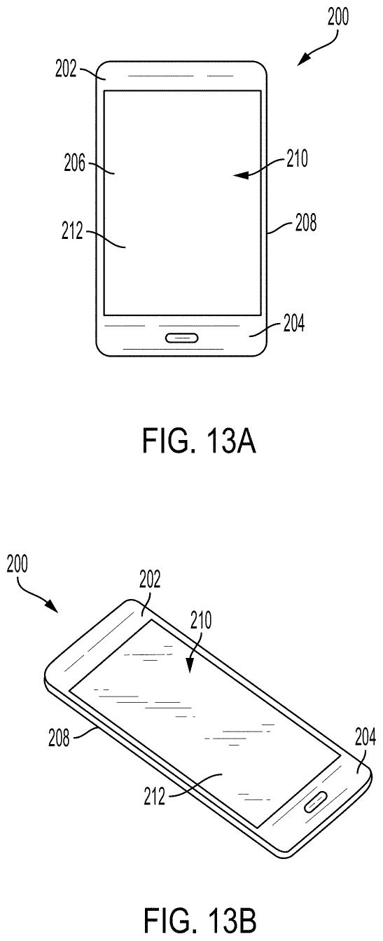

The durability of glass-ceramics was tested using drop testing. For the testing, Samp. 2 ion exchanged at 530° C. for 6 hours from Example 8 was compared to 0.6 mm thick glass-ceramic of the comparative composition that has been ion exchanged under the same conditions. Samp. 3 ion exchanged at 530° C. for 4 hours from Example 8 was compared to 0.5 mm thick glass-ceramic of the comparative composition that has been ion exchanged under the same conditions. The samples were attached to a Corning Clubmehd puck and dropped on 80 grit sandpaper from heights at 10 cm increments up to 220 cm and failure was recorded. FIG. 11. In FIG. 11 the broken (dotted) circles represent failures and solid circles represent survivors.

### Example 10

The testing is conducted using a conospherical diamond tip (90 degree angle/10 μm radius). The diamond tip comes into contact with the surface of the material, a force of 0.05N I sapplied, and then the tip is moved 10 mm across the sample while increasing the load from 0.05 N to 1.6 N. Once the scratch is completed, the tip is removed from the surface of the material.

FIG. 12A shows the scratch test results on a 0.5 mm thick glass-ceramic of Samp. 1 that were not chemically strengthened, but were cerammed at 575° C. for 4 hours and at 735° C. for an additional hour. FIG. 12B shows the scratch test results on a 0.6 mm thick glass-ceramic of the comparative sample shown in Table 2 and cerammed at 580° C. for 2.75 hours an at 755° C. for an additional 0.75 hours.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A glass-ceramic article comprising:
greater than or equal to 65.00 wt. % and less than or equal to 80.00 wt. % SiO₂;
greater than 4.00 wt. % and less than or equal to 12.00 wt. % Al₂O₃;
greater than or equal to 0.10 wt. % and less than or equal to 3.5 wt. % P₂O₅;
greater than or equal to 8.00 wt. % and less than or equal to 17.00 wt. % Li₂O;
greater than or equal to 4.00 wt. % and less than or equal to 15.00 wt. % ZrO₂; and
greater than or equal to 0.05 wt. % and less than or equal to 4.00 wt. % CaO.

2. The glass-ceramic article of claim 1, wherein the glass-ceramic article has a haze less than 0.15 measured on a 0.6 mm thick glass-ceramic article using a BYK Hazegard I Pro Setup.

3. The glass-ceramic article of claim 1, wherein the glass-ceramic article has a haze less than 0.12 measured on a 0.6 mm thick glass-ceramic article using a BYK Hazegard I Pro Setup.

4. The glass-ceramic article of claim 1, wherein the glass-ceramic article has an average transmittance of 85% or greater measured at wavelengths of 450 nm to 800 nm.

5. The glass-ceramic article of claim 1, wherein the glass-ceramic article comprises:
greater than or equal to 30 wt % and less than or equal to 50 wt % lithium disilicate;
greater than or equal to 30 wt % and less than or equal to 50 wt % petalite; and
less than 5 wt % of a sum of crystalline phases other than lithium disilicate and petalite.

6. The glass-ceramic article of claim 1, wherein the glass-ceramic article comprises greater than or equal to 5 wt % and less than or equal to 20 wt % residual amorphous glass.

7. The glass-ceramic article of claim 1, wherein the glass-ceramic article has a weight ratio of lithium disilicate to petalite that is greater than or equal to 0.5 and less than or equal to 1.5.

8. The glass article of claim 1, comprising greater than or equal to 68.00 wt. % and less than or equal to 74.00 wt. % SiO₂.

9. The glass-ceramic article of claim 1, comprising greater than 5.00 wt. % and less than or equal to 9.00 wt. % Al₂O₃.

10. The glass-ceramic article of claim 1, comprising greater than or equal to 1.00 wt. % and less than or equal to 3.00 wt. % P₂O₅.

11. The glass-ceramic article of claim 1, comprising greater than or equal to 9.00 wt. % and less than or equal to 14.00 wt. % Li₂O.

12. The glass-ceramic article of claim 1, comprising greater than or equal to 4.50 wt. % and less than or equal to 8.00 wt. % ZrO₂.

13. The glass-ceramic article of claim 1, comprising greater than or equal to 0.10 wt. % and less than or equal to 1.00 wt. % CaO.

14. The glass-ceramic article of claim 1, comprising greater than or equal to 0.01 wt % and less than or equal to 0.5 wt % SnO₂.

15. The glass-ceramic article of claim 1, wherein the glass-ceramic article has a thickness that is greater than or equal to 0.1 mm and less than or equal to 2.0 mm.

16. The glass-ceramic article of claim 1, wherein the glass-ceramic article has a thickness that is greater than or equal to 0.1 mm and less than or equal to 1.0 mm.

17. An electronic device comprising:
a housing,
a display,
a cover substrate adjacent to the display, wherein the cover substrate comprises the glass-ceramic article of claim 1.

18. A strengthened glass-ceramic article comprising:
a first surface;
a second surface; and
a thickness t extending from the first surface to the second surface, wherein
the strengthened glass-ceramic article has a surface compressive stress at the first surface,
stress transitions from compressive stress to a tensile stress at a depth from greater than or equal to 0.15 t and less than or equal to 0.25 t measured from the first surface toward a centerline of the strengthened glass-ceramic article, and
the strengthened glass-ceramic article has a maximum central tension mCT, and an absolute value of the surface compressive stress measured at the first surface is greater than or equal to 1.5 mCT and less than or equal to 2.5 mCT.

19. The strengthened glass-ceramic article of claim 18, wherein a compressive stress decreases with increasing thickness measured from the first surface of the strengthened glass-ceramic article to the centerline of the strengthened glass-ceramic article in a linear function from a thickness of greater than or equal to 0.07 t to a thickness of 0.26 t.

20. The strengthened glass-ceramic article of claim 18, wherein the strengthened glass-ceramic article has a compressive stress that is greater than or equal to 250 MPa and less than or equal to 400 MPa.
